(19) United States
(12) Patent Application Publication
(10) Pub. No.: US 2025/0008810 A1
(43) Pub. Date: Jan. 2, 2025

(54) DISPLAY DEVICE AND METHOD FOR FABRICATION THEREOF

(71) Applicant: Samsung Display Co., LTD., Yongin-si (KR)

(72) Inventors: Joon Yong PARK, Yongin-si (KR); Su Kyoung YANG, Yongin-si (KR); Dong Min LEE, Yongin-si (KR); Hyun Eok SHIN, Yongin-si (KR)

(21) Appl. No.: 18/628,716

(22) Filed: Apr. 6, 2024

(30) Foreign Application Priority Data
Jun. 27, 2023 (KR) 10-2023-0082454

(51) Int. Cl. H10K 59/80; H10K 59/12; H10K 59/122; H10K 71/40; H10K 71/60; H10K 102/00; H10K 102/10

(52) U.S. Cl. CPC H10K 59/80517; H10K 59/1201; H10K 59/122; H10K 71/40; H10K 71/60; H10K 2102/103; H10K 2102/351

(57) ABSTRACT

A display device includes a first pixel electrode disposed on a substrate and including a main portion and an edge portion, a pixel defining film disposed on the substrate, including a body portion and a protrusion portion, and exposing the first pixel electrode, a first light-emitting layer on the first pixel electrode, a first common electrode on the first light-emitting layer, a first bank layer on the pixel defining film, and a second bank layer disposed on the first bank layer and including a side surface protruding further than a side surface of the first bank layer. A thickness of the edge portion of the first pixel electrode is greater than a thickness of the main portion of the first pixel electrode, and a width of the protrusion portion of the pixel defining film is greater than a width of the edge portion of the first pixel electrode.

This application claims priority to Korean Patent Application No. 10-2023-0082454, filed on Jun. 27, 2023, and all the benefits accruing therefrom under 35 U.S.C. § 119, the content of which in its entirety is herein incorporated by reference.

### BACKGROUND

### 1. Field

The disclosure relates to a display device and a method for fabrication thereof.

### 2. Description of the Related Art

As the information society develops, the demand for display devices for displaying images has increased and diversified. For example, display devices have been applied to various electronic devices such as smartphones, digital cameras, laptop computers, navigation devices, and smart televisions. The display devices may be flat panel display devices such as liquid crystal display devices, field emission display devices, or organic light-emitting display devices. Among such flat panel display devices, a light-emitting display device may display an image without a backlight unit providing light to a display panel because each of pixels of the display panel includes light-emitting elements that may emit light by themselves.

Recently, the display devices are applied to glasses-type devices for providing virtual reality and augmented reality. The display device is implemented in a substantially small size of 2 inches or less in order to be applied to the glasses-type device, but should have a relatively high pixel integration degree in order to be implemented with relatively high resolution. In an embodiment, the display device may have a relatively high pixel integration degree of 1,000 pixels per inch (“PPI”) or more.

### SUMMARY

When the display device is implemented in the substantially small size but has the relatively high pixel integration degree as described above, areas of emission areas in which light-emitting elements are disposed are reduced, and thus, it is difficult to implement light-emitting elements separated from each other for each emission area through a mask process.

Features of the disclosure provide a display device capable of forming light-emitting elements separated from each other for each emission area without a mask process.

Features of the disclosure also provide a display device in which work functions of pixel electrodes does not decrease and hole injection capability are excellent even though the pixel electrodes are exposed to plasma during processes for fabrication of the display device.

However, features of the disclosure are not restricted to those set forth herein. The above and other features of the disclosure will become more apparent to one of ordinary skill in the art to which the disclosure pertains by referencing the detailed description of the disclosure given below.

In an embodiment of the disclosure, a display device includes a first pixel electrode disposed on a substrate and including a main portion and an edge portion surrounding the main portion, a pixel defining film disposed on the substrate, including a body portion and a protrusion portion protruding from the body portion, and exposing the first pixel electrode, a first light-emitting layer disposed on the first pixel electrode, a first common electrode disposed on the first light-emitting layer, a first bank layer disposed on the pixel defining film, and a second bank layer disposed on the first bank layer and including a side surface protruding further than a side surface of the first bank layer, where a thickness of the edge portion of the first pixel electrode is greater than a thickness of the main portion of the first pixel electrode, and a width of the protrusion portion of the pixel defining film is greater than a width of the edge portion of the first pixel electrode.

In an embodiment, a difference between the thickness of the edge portion of the first pixel electrode and the thickness of the main portion of the first pixel electrode may be about 150 angstroms (Å) to about 300 Å.

In an embodiment, the first pixel electrode may include a lower transparent electrode layer disposed on the substrate, a metal electrode layer disposed on the lower transparent electrode layer, and an upper transparent electrode layer disposed on the metal electrode layer, and a thickness of the edge portion of the upper transparent electrode layer may be greater than a thickness of the main portion of the upper transparent electrode layer.

In an embodiment, the thickness of the edge portion of the upper transparent electrode layer may be about 400 Å to about 700 Å, and the thickness of the main portion of the upper transparent electrode layer may be about 100 Å to about 500 Å.

In an embodiment, a thickness of the lower transparent electrode layer may be about 30 Å to about 100 Å, and a thickness of the metal electrode layer may be about 700 Å to about 1000 Å.

In an embodiment, the lower transparent electrode layer and the upper transparent electrode layer may include indium tin oxide (“ITO”), and the metal electrode layer may include silver (Ag).

In an embodiment, a lower surface of the protrusion portion of the pixel defining film may contact the edge portion of the first pixel electrode and the first light-emitting layer.

In an embodiment, a width at which a side surface of the protrusion portion of the pixel defining film protrudes further than the side surface of the first bank layer may be greater than a width at which the side surface of the second bank layer protrudes further than the side surface of the first bank layer.

In an embodiment, the first bank layer may include aluminum (Al), and the second bank layer may include titanium (Ti).

In an embodiment, the first common electrode may contact the first bank layer.

In an embodiment, a maximum distance from the substrate to the first common electrode may be smaller than a maximum distance from the substrate to the first bank layer.

In an embodiment, the display device may further include a first inorganic layer disposed on an upper surface of the first common electrode, the side surface of the first bank layer, and a lower surface and an upper surface of the second bank layer.

In an embodiment, the display device may further include a second pixel electrode disposed to be spaced apart from the first pixel electrode on the substrate and including a main portion and an edge portion surrounding the main portion, a second light-emitting layer disposed on the second pixel electrode, a second common electrode disposed on the second light-emitting layer and spaced apart from the first common electrode, and a second inorganic layer disposed on an upper surface of the second common electrode, the side surface of the first bank layer, and the lower surface and the upper surface of the second bank layer, where the pixel defining film may expose the second pixel electrode, the first inorganic layer and the second inorganic layer may be spaced apart from each other, and a portion of the second bank layer may be exposed in a space between the first inorganic layer and the second inorganic layer spaced apart from each other.

In an embodiment, the display device may further include a first organic pattern disposed on the second bank layer and including a same material as that of the first light-emitting layer, and a first electrode pattern disposed on the first organic pattern and including a same material as that of the first common electrode, where the first light-emitting layer and the first organic pattern may be separated from each other, and the first common electrode and the first electrode pattern are separated from each other.

In an embodiment of the disclosure, a method of fabrication of a display device includes forming a plurality of pixel electrodes spaced apart from each other on a substrate; forming a pixel defining material layer on the plurality of pixel electrodes, forming a first bank material layer on the pixel defining material layer, and forming a second bank material layer on the first bank material layer; defining a hole exposing a first pixel electrode of the plurality of pixel electrodes by etching the pixel defining material layer, the first bank material layer, and the second bank material layer; etching a portion of the first pixel electrode so that portions of a lower surface of the pixel defining material layer are exposed while etching side surfaces of the first bank material layer exposed through the hole so that portions of a lower surface of the second bank material layer are exposed; forming a first light-emitting layer on the first pixel electrode and forming a first common electrode on the first light-emitting layer; and forming a first inorganic material layer on the first common electrode.

In an embodiment, the forming the plurality of pixel electrodes spaced apart from each other on the substrate may include forming an amorphous ITO electrode including hydrogen through a sputtering process under at an atmosphere of a mixed gas including hydrogen and argon.

In an embodiment, the method for fabrication of a display device of may further include between the etching the portion of the first pixel electrode while etching the side surfaces of the first bank material layer and the forming the first light-emitting layer on the first pixel electrode, crystallizing the ITO electrode by heat-treating the first pixel electrode to remove hydrogen in the ITO electrode.

In an embodiment, in the etching the portion of the first pixel electrode so that the portions of the lower surface of the pixel defining material layer are exposed while etching the side surfaces of the first bank material layer exposed through the hole so that the portions of the lower surface of the second bank material layer are exposed, the first pixel electrode including a main portion and an edge portion surrounding the main portion may be formed, and a thickness of the edge portion of the first pixel electrode may be greater than a thickness of the main portion of the first pixel electrode.

In an embodiment, in the forming the first light-emitting layer on the first pixel electrode and the forming the first common electrode on the first light-emitting layer, a first organic pattern material layer separated from the first light-emitting layer may be formed on the second bank material layer, and a first electrode pattern material layer separated from the first common electrode may be formed on the first organic pattern material layer, and in the forming the first inorganic material layer on the first common electrode, the first inorganic material layer connected without being disconnected may be formed on the first common electrode and the first electrode pattern material layer.

In an embodiment, the method for fabrication of a display device may further include forming a mask pattern on the first inorganic material layer overlapping the first pixel electrode and etching the first organic pattern material layer, the first electrode pattern material layer, and the first inorganic material layer that are not covered by the mask pattern through an etching process.

With a display device and a method for fabrication thereof in an embodiment, by disposing a pixel defining film on pixel electrodes including edges having great thicknesses, it is possible to prevent the occurrence of a mura in the display device.

In addition, with the method for fabrication of a display device in an embodiment, a separate layer for protecting the pixel electrodes is not desired, such that a process may be simplified.

The effects of the disclosure are not limited to the aforementioned effects, and various other effects are included in the specification.

### BRIEF DESCRIPTION OF THE DRAWINGS

The above and other features and features of the disclosure will become more apparent by describing in detail embodiments thereof with reference to the attached drawings, in which:

FIG. 1 is a schematic perspective view of an embodiment of an electronic device;

FIG. 2 is a perspective view illustrating an embodiment of a display device included in the electronic device;

FIG. 3 is a cross-sectional view of the display device of FIG. 2 viewed from the side;

FIG. 4 is a plan view illustrating an embodiment of a display layer of the display device;

FIG. 5 is a plan view illustrating an embodiment of an arrangement of light-emitting elements, trace patterns, and a second bank layer of the display device;

FIG. 6 is a cross-sectional view illustrating an embodiment of a portion of the display device;

FIG. 7 is an enlarged view illustrating a first emission area, specifically, area A1, of FIG. 6;

FIG. 8 is an enlarged view illustrating area A2 of FIG. 7;

FIG. 9 is a flowchart illustrating an embodiment of processes for fabrication of the display device; and

FIGS. 10 to 18 are cross-sectional views sequentially illustrating an embodiment of the processes for fabrication of the display device.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). The term such as “about” can mean within one or more standard deviations, or within ±30%, 20%, 10%, 5% of the stated value, for example.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

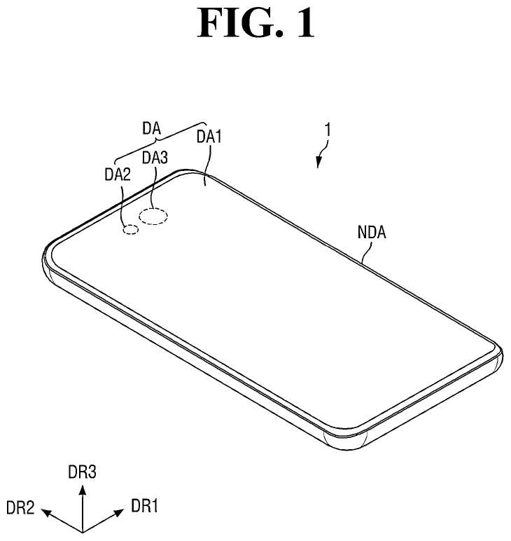

FIG. 1 is a schematic perspective view of an embodiment of a display device.

Referring to FIG. 1, an electronic device 1 displays a moving image or a still image. The electronic device 1 may refer to all electronic devices that provide display screens. In an embodiment, televisions, laptop computers, monitors, billboards, the Internet of Things (“IoT”), mobile phones, smartphones, tablet personal computers (“PCs”), electronic watches, smart watches, watch phones, head mounted displays, mobile communication terminals, electronic notebooks, electronic books, portable multimedia players (“PMPs”), navigation devices, game machines, digital cameras, camcorders, or the like, which provide display screens, may be included in the electronic device 1.

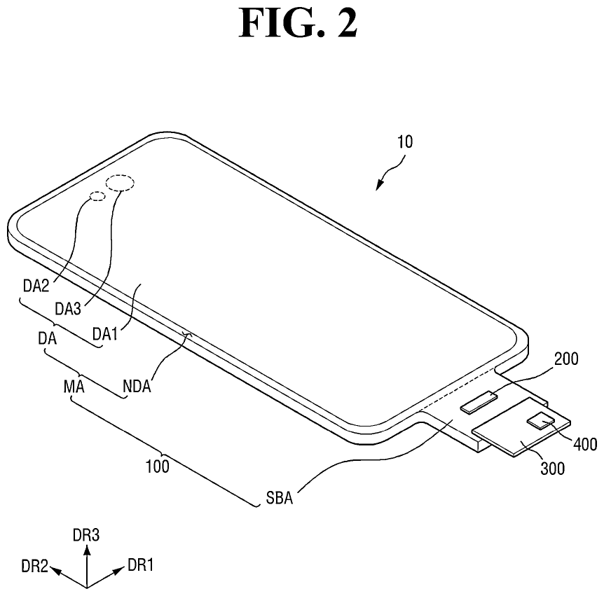

The electronic device 1 may include a display device 10 (refer to FIG. 2) providing a display screen. In embodiments, the display device may include an inorganic light-emitting diode display device, an organic light-emitting display device, a quantum dot light-emitting display device, a plasma display device, a field emission display device, or the like. Hereinafter, a case where an organic light-emitting diode display device is applied in an embodiment of the display device will be described by way of example, but the disclosure is not limited thereto, and the same technical spirit may be applied to other display devices when applicable.

A shape of the electronic device 1 may be variously modified. In an embodiment, the electronic device 1 may have a shape such as a quadrangular shape, e.g., rectangular shape with a width greater than a length, a rectangular shape with a length greater than a width, a square shape, a rectangular shape with rounded corners (vertices), or other polygonal shapes, or a circular shape, for example. A shape of a display area DA of the electronic device 1 may also be similar to an overall shape of the electronic device 1. In FIG. 1, the electronic device 1 having a rectangular shape with a great length in a second direction DR2 has been illustrated.

The electronic device 1 may include a display area DA and a non-display area NDA. The display area DA is an area in which a screen is displayed, and the non-display area NDA is an area in which the screen is not displayed. The display area DA may also be also referred to as an active area, and the non-display area NDA may also be also referred to as a non-active area. The display area DA may occupy substantially the center of the electronic device 1.

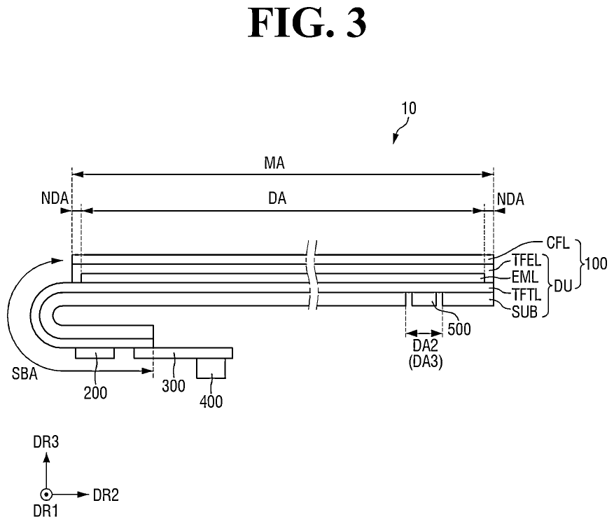

The display area DA may include a first display area DA1, a second display area DA2, and a third display area DA3. The second display area DA2 and the third display area DA3 may be areas in which components for adding various functions to the electronic device 1 are disposed, and may correspond to component areas. The component may be an optical device 500 illustrated in FIG. 3.

FIG. 2 is a perspective view illustrating an embodiment of a display device included in the electronic device.

Referring to FIG. 2, the electronic device 1 in an embodiment may include a display device 10. The display device 10 may provide a screen displayed by the electronic device 1. The display device 10 may have a shape similar to that of the electronic device 1 in a plan view. In an embodiment, the display device 10 may have a shape similar to a quadrangular shape, e.g., rectangular shape having short sides in a first direction DR1 and long sides in the second direction DR2, for example. A corner where the short side in the first direction DR1 and the long side in the second direction DR2 meet may be rounded with a curvature, but is not limited thereto, and may also be right-angled. The shape of the display device 10 in a plan view is not limited to the rectangular shape, and may be a shape similar to other polygonal shapes, a circular shape, or an elliptical shape.

The display device 10 may include a display panel 100, a display driver 200, a circuit board 300, and a touch driver 400.

The display panel 100 may include a main area MA and a sub-area SBA.

The main area MA may include a display area DA including pixels displaying an image and a non-display area NDA disposed around the display area DA. The display area DA may include a first display area DA1, a second display area DA2, and a third display area DA3. The display area DA may emit light from a plurality of emission areas or a plurality of opening areas. In an embodiment, the display panel 100 may include pixel circuits including switching elements, a pixel defining film defining the emission areas or the opening areas, and self-light-emitting elements, for example.

In an embodiment, the self-light-emitting element may include at least one of an organic light-emitting diode (“LED”) including an organic light-emitting layer, a quantum dot LED including a quantum dot light-emitting layer, an inorganic LED including an inorganic semiconductor, and a micro LED, for example, but is not limited thereto.

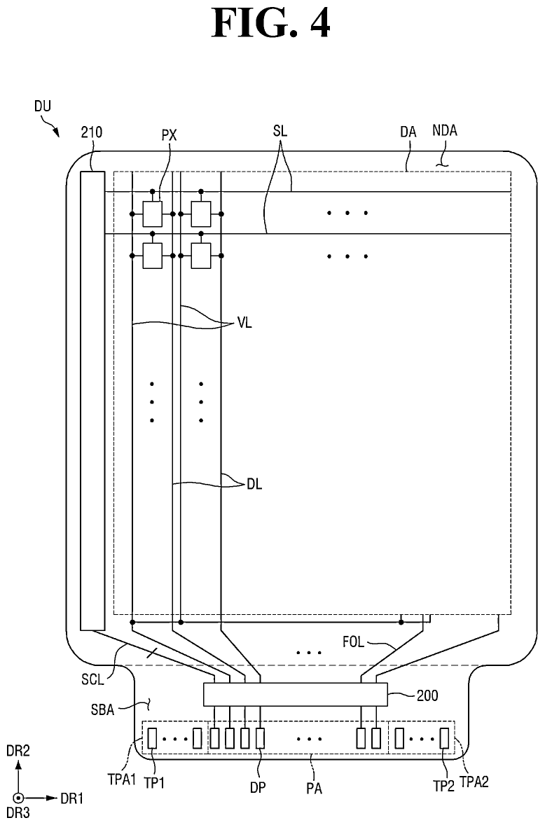

The non-display area NDA may be an area outside the display area DA. The non-display area NDA may be defined as an edge area of the main area MA of the display panel 100. The non-display area NDA may include a scan driver 210 (refer to FIG. 4) supplying scan signals to scan lines and fan-out lines FOL (refer to FIG. 4) connecting the display driver 200 and the display area DA to each other.

The sub-area SBA may be an area extending from one side of the main area MA. The sub-area SBA may include a flexible material that may be bent, folded, and rolled. In an embodiment, when the sub-area SBA is bent, the sub-area SBA may overlap the main area MA in a thickness direction (third direction DR3), for example. The sub-area SBA may include the display driver 200 and pad parts connected to the circuit board 300. In another embodiment, the sub-area SBA may be omitted, and the display driver 200 and the pad parts may be disposed in the non-display area NDA.

The display driver 200 may output signals and voltages for driving the display panel 100. The display driver 200 may supply data voltages to data lines. The display driver 200 may supply source voltages to power lines and supply scan control signals to the scan driver. The display driver 200 may be formed as an integrated circuit (“IC”) and disposed (e.g., mounted) on the display panel 100 in a chip on glass (“COG”) manner, a chip on plastic (“COP”) manner, or an ultrasonic bonding manner. In an embodiment, the display driver 200 may be disposed in the sub-area SBA, and may overlap the main area MA in the thickness direction (third direction DR3) by bending of the sub-area SBA. In another embodiment, the display driver 200 may be disposed (e.g., mounted) on the circuit board 300.

The circuit board 300 may be attached onto the pad parts of the display panel 100 using an anisotropic conductive film (“ACF”). Lead lines of the circuit board 300 may be electrically connected to the pad parts of the display panel 100. The circuit board 300 may be a flexible printed circuit board, a printed circuit board, or a flexible film such as a chip on film.

The touch driver 400 may be disposed (e.g., mounted) on the circuit board 300. The touch driver 400 may be connected to a touch sensing unit of the display panel 100. The touch driver 400 may supply touch driving signals to a plurality of touch electrodes of the touch sensing unit and sense change amounts in capacitance between the plurality of touch electrodes. In an embodiment, the touch driving signal may be a pulse signal having a predetermined frequency, for example. The touch driver 400 may decide whether or not a touch input has been generated and calculate touch coordinates, based on the amounts of change in capacitance between the plurality of touch electrodes. The touch driver 400 may be formed as an IC.

FIG. 3 is a cross-sectional view of the display device of FIG. 2 viewed from the side.

Referring to FIG. 3, the display panel 100 may include a display layer DU and a color filter layer CFL. The display layer DU may include a substrate SUB, a thin film transistor layer TFTL, a light-emitting element layer EML, and a thin film encapsulation layer TFEL.

The substrate SUB may be a base substrate or a base member. The substrate SUB may be a flexible substrate that may be bent, folded, and rolled. In an embodiment, the substrate SUB may include a polymer resin such as polyimide (“PI”), for example, but is not limited thereto. In another embodiment, the substrate SUB may include a glass material or a metal material.

The thin film transistor layer TFTL may be disposed on the substrate SUB. The thin film transistor layer TFTL may include a plurality of thin film transistors constituting pixel circuits of pixels. The thin film transistor layer TFTL may further include scan lines, data lines, power lines, scan control lines, fan-out lines connecting the display driver 200 and the data lines to each other, and lead lines connecting the display driver 200 and the pad parts to each other. Each of the thin film transistors may include a semiconductor region, a source electrode, a drain electrode, and a gate electrode. In an embodiment, when the scan driver is formed on one side of the non-display area NDA of the display panel 100, the scan driver may include thin film transistors, for example.

The thin film transistor layer TFTL may be disposed in the display area DA, the non-display area NDA, and the sub-area SBA. The thin film transistors of each of the pixels, the scan lines, the data lines, and the power lines of the thin film transistor layer TFTL may be disposed in the display area DA. The scan control lines and the fan-out lines of the thin film transistor layer TFTL may be disposed in the non-display area NDA. The lead lines of the thin film transistor layer TFTL may be disposed in the sub-area SBA.

The light-emitting element layer EML may be disposed on the thin film transistor layer TFTL. The light-emitting element layer EML may include a plurality of light-emitting elements each including a first electrode, a second electrode, and a light-emitting layer to emit light and a pixel defining film defining the pixels. The plurality of light-emitting elements of the light-emitting element layer EML may be disposed in the display area DA.

In an embodiment, the light-emitting layer may be an organic light-emitting layer including an organic material. The light-emitting layer may include a hole transporting layer, an organic light-emitting layer, and an electron transporting layer. When the first electrode receives a voltage through the thin film transistor of the thin film transistor layer TFTL and the second electrode receives a cathode voltage, holes and electrons may move to the organic light-emitting layer through the hole transporting layer and the electron transporting layer, respectively, and may be combined with each other in the organic light-emitting layer to emit light.

In another embodiment, the light-emitting element may include a quantum dot light-emitting diode including a quantum dot light-emitting layer, an inorganic light-emitting diode including an inorganic semiconductor, or a micro light-emitting diode.

The thin film encapsulation layer TFEL may cover an upper surface and side surfaces of the light-emitting element layer EML, and may protect the light-emitting element layer EML. The thin film encapsulation layer TFEL may include at least one inorganic film and at least one organic film for encapsulating the light-emitting element layer EML.

In an embodiment, a touch sensing layer may be disposed on the display layer DU. The touch sensing layer may obtain coordinates of a touch input point in a capacitance manner. The touch sensing layer may obtain coordinate information of a touched point in a self-capacitance manner or a mutual capacitance manner in an embodiment of the capacitance manner, but is not limited thereto.

The color filter layer CFL may be disposed on the thin film encapsulation layer TFEL. The color filter layer CFL may include a plurality of color filters each corresponding to the plurality of emission areas. Each of the color filters may selectively transmit light of a predetermined wavelength therethrough and block or absorb light of other wavelengths. The color filter layer CFL may absorb some of light introduced from the outside of the display device 10 to reduce reflected light by external light. Accordingly, the color filter layer CFL may prevent distortion of colors due to external light reflection.

Since the color filter layer CFL is directly disposed on the thin film encapsulation layer TFEL, a separate substrate for the color filter layer CFL may not be desired in the display device 10. Accordingly, a thickness of the display device 10 may be relatively small.

In some embodiments, the display device 10 may further include an optical device 500. The optical device 500 may be disposed in the second display area DA2 or the third display area DA3. The optical device 500 may emit or receive light of infrared, ultraviolet, and visible light bands. In an embodiment, the optical device 500 may be an optical sensor sensing light incident on the display device 10, such as a proximity sensor, an illuminance sensor, a camera sensor, a fingerprint sensor, or an image sensor, for example.

FIG. 4 is a plan view illustrating an embodiment of a display layer of the display device.

Referring to FIG. 4, the display layer DU may include a display area DA and a non-display area NDA.

The display area DA may be disposed at the center of the display panel 100. A plurality of pixels PX, a plurality of scan lines SL, a plurality of data lines DL, and a plurality of power lines VL may be disposed in the display area DA. Each of the plurality of pixels PX may be defined as a minimum unit emitting light.

The plurality of scan lines SL may supply scan signals received from the scan driver 210 to the plurality of pixels PX. The plurality of scan lines SL may extend in the first direction DR1, and may be spaced apart from each other in the second direction DR2 crossing the first direction DR1.

The plurality of data lines DL may supply data voltages received from the display driver 200 to the plurality of pixels PX. The plurality of data lines DL may extend in the second direction DR2, and may be spaced apart from each other in the first direction DR1.

The plurality of power lines VL may supply a source voltage received from the display driver 200 to the plurality of pixels PX. Here, the source voltage may be at least one of a driving voltage, an initialization voltage, a reference voltage, and a relatively low potential voltage. The plurality of power lines VL may extend in the second direction DR2, and may be spaced apart from each other in the first direction DR1.

The non-display areas NDA may surround the display area DA. The scan driver 210, fan-out lines FOL, and scan control lines SCL may be disposed in the non-display area NDA. The scan driver 210 may generate a plurality of scan signals based on scan control signals, and may sequentially supply the plurality of scan signals to the plurality of scan lines SL according to a set order.

The fan-out lines FOL may extend from the display driver 200 to the display area DA. The fan-out lines FOL may supply the data voltages received from the display driver 200 to the plurality of data lines DL.

The scan control lines SCL may extend from the display driver 200 to the scan driver 210. The scan control lines SCL may supply the scan control signals received from the display driver 200 to the scan driver 210.

The sub-area SBA may include the display driver 200, a pad area PA, and first and second touch pad areas TPA1 and TPA2.

The display driver 200 may output signals and voltages for driving the display panel 100 to the fan-out lines FOL. The display driver 200 may supply the data voltages to the data lines DL through the fan-out lines FOL. The data voltages may be supplied to the plurality of pixels PX, and may control luminance of the plurality of pixels PX. The display driver 200 may supply the scan control signals to the scan driver 210 through the scan control lines SCL.

The pad area PA, the first touch pad area TPA1, and the second touch pad area TPA2 may be disposed at an edge of the sub-area SBA. The pad area PA, the first touch pad area TPA1, and the second touch pad area TPA2 may be electrically connected to the circuit board 300 using a material such as an ACF or a self assembly anisotropic conductive paste (“SAP”). In an embodiment, the first touch pad area TPA1 may include first touch pad part TP1, and the second touch pad area TPA2 may include a second pad part TP2.

The pad area PA may include a plurality of display pad parts DP. The plurality of display pad parts DP may be connected to a graphic system through the circuit board 300. The plurality of display pad parts DP may be connected to the circuit board 300 to receive digital video data, and may supply the digital video data to the display driver 200.

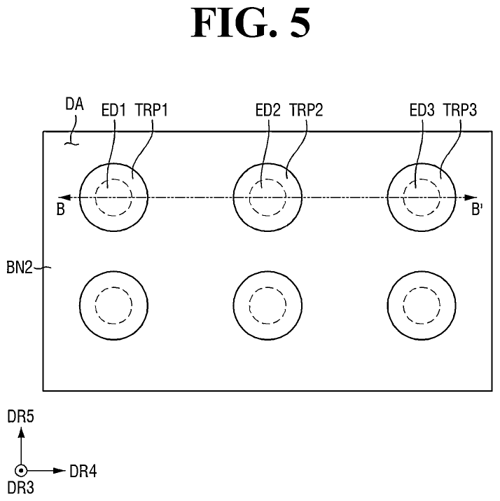

FIG. 5 is a plan view illustrating an embodiment of a portion of the display device. FIG. 5 is a plan view illustrating an arrangement of light-emitting elements ED1, ED2, and ED3, trace patterns TRP1, TRP2, and TRP3, and a second bank layer BN2 in the display area DA of the display device 10.

Referring to FIG. 5, the second bank layer BN2 may cover the display area DA, but expose portions of the display area DA. Openings are defined in exposed areas that are not covered with the second bank layer BN2, and the light-emitting elements ED1, ED2, and ED3 are disposed within the respective openings. The trace patterns TRP1, TRP2, and TRP3 are disposed on the second bank layer BN2 along contours of the exposed areas that are not covered with the second bank layer BN2. It has been illustrated in FIG. 5 that the exposed areas that are not covered with the second bank layer BN2 have a circular shape, but the exposed areas may have a polygonal shape such as a triangular shape, a quadrangular shape, or a hexagonal shape, and a shape of the trace patterns TRP1, TRP2, and TRP3 disposed along the contours of the exposed areas may also be changed. The trace patterns TRP1, TRP2, and TRP3 are disposed at a level above the second bank layer BN2, and the light-emitting elements ED1, ED2, and ED3 are disposed at a level below the second bank layer BN2.

The exposed areas that are not covered with the second bank layer BN2 may be spaced apart from each other in a fourth direction DR4 and may also be spaced apart from each other in a fifth direction DR5. The fourth direction DR4 is an arbitrary direction in a plan view including the first direction DR1 and the second direction DR2, and the fifth direction DR5 is a direction perpendicular to the fourth direction DR4. A shape and an arrangement of the exposed areas that are not covered with the second bank layer BN2 are not limited to those illustrated in FIG. 5, and the exposed areas that are not covered with the second bank layer BN2 may be disposed in a PENTILE™ type.

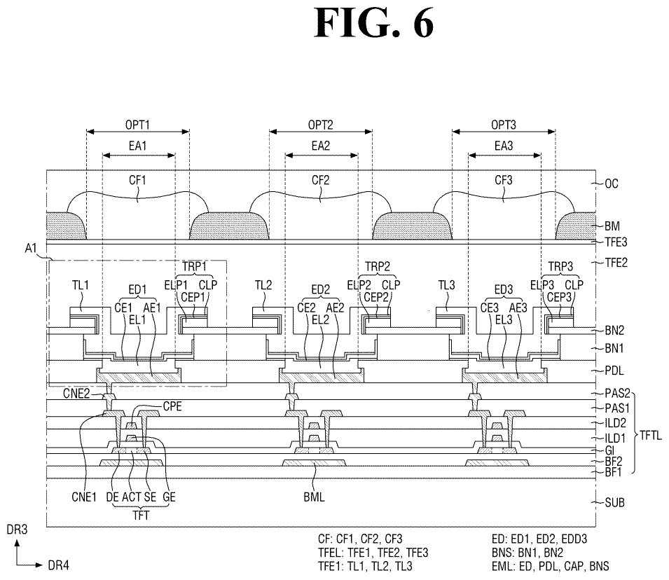

FIG. 6 is a cross-sectional view illustrating an embodiment of a portion of the display device. Specifically, FIG. 6 is a cross-sectional view taken along line B-B′ of FIG. 5, and illustrates an organic encapsulation film TFE2, a second inorganic encapsulation film TFE3, color filters CF1, CF2, and CF3, a light-blocking layer BM, and an overcoat layer OC that are disposed above the plan view of FIG. 5. FIG. 6 illustrates cross sections of the substrate SUB, the thin film transistor layer TFTL, the light-emitting element layer EML, and the thin film encapsulation layer TFEL of the display layer DU, and the color filter layer CFL.

Referring to FIG. 6, the display panel 100 of the display device 10 may include the display layer DU and the color filter layer CFL. The display layer DU may include the substrate SUB, the thin film transistor layer TFTL, the light-emitting element layer EML, and the thin film encapsulation layer TFEL. The display panel 100 may include the light-blocking layer BM disposed on the thin film encapsulation layer TFEL, and the color filters CF1, CF2, and CF3 of the color filter layer CFL may be disposed on the light-blocking layer BM.

The substrate SUB may be a base substrate or a base member. The substrate SUB may be a flexible substrate that may be bent, folded, and rolled. In an embodiment, the substrate SUB may include a polymer resin such as polyimide (“PI”), but is not limited thereto. In another embodiment, the substrate SUB may include a glass material or a metal material.

The thin film transistor layer TFTL may include a first buffer layer BF1, a bottom metal layer BML, a second buffer layer BF2, thin film transistors TFT, a gate insulating layer GI, a first inter-insulating layer ILD1, capacitor electrodes CPE, a second inter-insulating layer ILD2, first connection electrodes CNE1, a first passivation layer PAS1, second connection electrodes CNE2, and a second passivation layer PAS2.

The first buffer layer BF1 may be disposed on the substrate SUB. The first buffer layer BF1 may include an inorganic film capable of preventing permeation of air or moisture. In an embodiment, the first buffer layer BF1 may include a plurality of inorganic films that are alternately stacked, for example.

The bottom metal layer BML may be disposed on the first buffer layer BF1. In an embodiment, the bottom metal layer BML may be formed as a single layer or multiple layers including any one of molybdenum (Mo), aluminum (Al), chromium (Cr), gold (Au), titanium (Ti), nickel (Ni), neodymium (Nd), and copper (Cu), or alloys thereof, for example.

The second buffer layer BF2 may cover the first buffer layer BF1 and the bottom metal layer BML. The second buffer layer BF2 may include an inorganic film capable of preventing permeation of air or moisture. In an embodiment, the second buffer layer BF2 may include a plurality of inorganic films that are alternately stacked, for example.

The thin film transistor TFT may be disposed on the second buffer layer BF2, and may constitute a pixel circuit of each of the plurality of pixels. In an embodiment, the thin film transistor TFT may be a driving transistor or a switching transistor of the pixel circuit, for example. The thin film transistor TFT may include a semiconductor layer ACT, a source electrode SE, a drain electrode DE, and a gate electrode GE.

The semiconductor layer ACT may be disposed on the second buffer layer BF2. The semiconductor layer ACT may overlap the bottom metal layer BML and the gate electrode GE in the thickness direction DR3, and may be insulated from the gate electrode GE by the gate insulating layer GI. A material of the semiconductor layer ACT in portions of the semiconductor layer ACT may become conductors to form the source electrode SE and the drain electrode DE.

The gate electrode GE may be disposed on the gate insulating layer GI. The gate electrode GE may overlap the semiconductor layer ACT in the thickness direction DR3 with the gate insulating layer GI interposed therebetween.

The gate insulating layer GI may be disposed on the semiconductor layer ACT. In an embodiment, the gate insulating layer GI may cover the semiconductor layer ACT and the second buffer layer BF2, and may insulate the semiconductor layer ACT and the gate electrode GE from each other, for example. The gate insulating layer GI may define contact holes through which the first connection electrodes CNE1 penetrate.

The first inter-insulating layer ILD1 may cover the gate electrode GE and the gate insulating layer GI. The first inter-insulating layer ILD1 may define contact holes through which the first connection electrodes CNE1 penetrate. The contact holes of the first inter-insulating layer ILD1 may be connected to the contact holes of the gate insulating layer GI and contact holes of the second inter-insulating layer ILD2.

The capacitor electrodes CPE may be disposed on the first inter-insulating layer ILD1. The capacitor electrode CPE may overlap the gate electrode GE in the thickness direction DR3. The capacitor electrode CPE and the gate electrode GE may form capacitance.

The second inter-insulating layer ILD2 may cover the capacitor electrodes CPE and the first inter-insulating layer ILD1. The second inter-insulating layer ILD2 may define contact holes through which the first connection electrodes CNE1 penetrate. The contact holes of the second inter-insulating layer ILD2 may be connected to the contact holes of the first inter-insulating layer ILD1 and the contact holes of the gate insulating layer GI.

The first connection electrodes CNE1 may be disposed on the second inter-insulating layer ILD2. The first connection electrode CNE1 may electrically connect the drain electrode DE of the thin film transistor TFT and the second connection electrode CNE2 to each other. The first connection electrode CNE1 may be inserted into the contact holes defined in the second inter-insulating layer ILD2, the first inter-insulating layer ILD1, and the gate insulating layer GI to contact the drain electrode DE of the thin film transistor TFT.

The first passivation layer PAS1 may cover the first connection electrode CNE1 and the second inter-insulating layer ILD2. The first passivation layer PAS1 may protect the thin film transistor TFT. The first passivation layer PAS1 may define contact holes through which the second connection electrodes CNE2 penetrate.

The second connection electrodes CNE2 may be disposed on the first passivation layer PAS1. The second connection electrodes CNE2 may electrically connect the first connection electrodes CNE1 and pixel electrodes AE1, AE2, and AE3 of the light-emitting elements ED to each other. The second connection electrode CNE2 may be inserted into the contact hole defined in the first passivation layer PAS1 to contact the first connection electrode CNE1.

The second passivation layer PAS2 may cover the second connection electrodes CNE2 and the first passivation layer PAS1. The second passivation layer PAS2 may define contact holes through which the pixel electrodes AE1, AE2, and AE3 of the light-emitting elements ED penetrate.

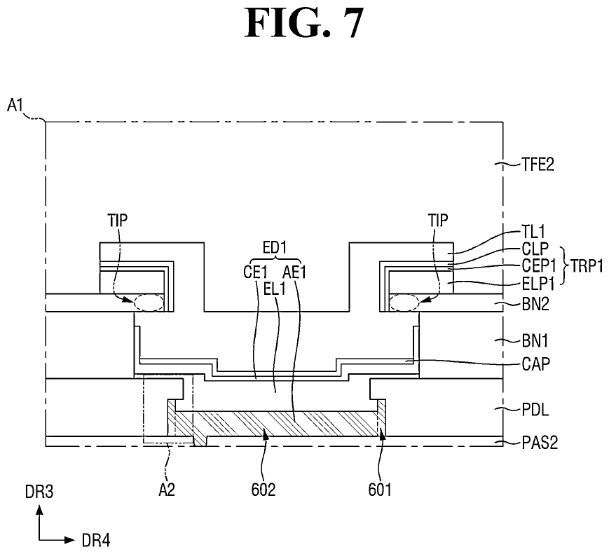

The light-emitting element layer EML may be disposed on the thin film transistor layer TFTL. The light-emitting element layer EML may include light-emitting elements ED, a pixel defining film PDL, capping layers CAP (refer to FIG. 7), and a bank structure BNS. The light-emitting elements ED may include the pixel electrodes AE1, AE2, and AE3, light-emitting layers EL1, EL2, and EL3, and common electrodes CE1, CE2, and CE3.

FIG. 7 is an enlarged view illustrating a first emission area, specifically, area A1, of FIG. 6.

Referring to FIG. 7 in addition FIG. 6, the display device 10 may include a plurality of emission areas EA1, EA2, and EA3 disposed in the display area DA. The emission areas EA1, EA2, and EA3 may include areas in which light is emitted from the light-emitting elements ED1, ED2, and ED3 and passes to the color filter layer CFL in the third direction DR3. The emission areas EA1, EA2, and EA3 may include first emission areas EA1, second emission areas EA2, and third emission areas EA3 that are spaced apart from each other and emit light of different colors.

In an embodiment, areas or sizes of the first to third emission areas EA1, EA2, and EA3 may be the same as each other. In an embodiment, in the display device 10, the first emission area EA1, the second emission area EA2, and the third emission area EA3 may have the same area, for example. However, the disclosure is not limited thereto. In the display device 10, areas or sizes of the first to third emission areas EA1, EA2, and EA3 may be different from each other. In an embodiment, an area of the second emission area EA2 may be greater than areas of the first emission area EA1 and the third emission area EA3, and an area of the third emission area EA3 may be greater than an area of the first emission area EA1. Intensities of the light emitted from the emission areas EA1, EA2, and EA3 may change depending on the areas of the emission areas EA1, EA2, and EA3, and a color feeling of a screen displayed on the display device 10 or the electronic device 1 may be controlled by adjusting the areas of the emission areas EA1, EA2, and EA3. In an embodiment of FIG. 6, it has been illustrated that the areas of the emission areas EA1, EA2, and EA3 are the same as each other, but the disclosure is not limited thereto.

In the display device 10, one first emission area EA1, one second emission area EA2, and one third emission area EA3 disposed adjacent to each other may form one pixel group. One pixel group may include the emission areas EA1, EA2, and EA3 emitting light of different colors to express a white gradation. However, the disclosure is not limited thereto, and a combination of the emission areas EA1, EA2, and EA3 constituting one pixel group may be variously modified depending on an arrangement of the emission areas EA1, EA2, and EA3, colors of the light emitted by the emission areas EA1, EA2, and EA3, or the like.

A plurality of openings defined in the bank structure BNS of the light-emitting element layer EML is defined along a boundary of the bank structure BNS. A first bank layer BN1 and a second bank layer BN2 of the bank structure BNS may have a shape in which they surround the emission areas EA1, EA2, and EA3. The openings may include the first to third emission areas EA1, EA2, and EA3.

The display device 10 may include a plurality of light-emitting elements ED1, ED2, and ED3 disposed in different emission areas EA1, EA2, and EA3. The light-emitting elements ED1, ED2, and ED3 may include a first light-emitting element EDI disposed in the first emission area EA1, a second light-emitting element ED2 disposed in the second emission area EA2, and a third light-emitting element ED3 disposed in the third emission area EA3. The light-emitting elements ED1, ED2, and ED3 may include the pixel electrodes AE1, AE2, and AE3, the light-emitting layers EL1, EL2, and EL3, and the common electrodes CE1, CE2, and CE3, respectively, and the light-emitting elements ED1, ED2, and ED3 disposed in the different emission areas EA1, EA2, and EA3 may emit light of different colors depending on materials of the light-emitting layers EL1, EL2, and EL3, respectively. In an embodiment, the first light-emitting element ED1 disposed in the first emission area EA1 may emit first light, which is red light, having a peak wavelength in the range of about 610 nanometers (nm) to about 650 nm, the second light-emitting element ED2 disposed in the second emission area EA2 may emit second light, which is green light, having a peak wavelength in the range of about 510 nm to about 550 nm, and the third light-emitting element ED3 disposed in the third emission area EA3 may emit third light, which is blue light, having a peak wavelength in the range of about 440 nm to about 480 nm. The first to third emission areas EA1, EA2, and EA3 constituting one pixel may include the light-emitting elements ED1, ED2, and ED3 emitting the light of the different colors to express a white gradation.

The pixel electrodes AE1, AE2, and AE3 may be disposed on the second passivation layer PAS2. The pixel electrodes AE1, AE2, and AE3 may be disposed in the plurality of emission areas EA1, EA2, and EA3, respectively. The pixel electrodes AE1, AE2, and AE3 may include a first pixel electrode AE1 disposed in the first emission area EA1, a second pixel electrode AE2 disposed in the second emission area EA2, and a third pixel electrode AE3 disposed in the third emission area EA3. The first pixel electrode AE1, the second pixel electrode AE2, and the third pixel electrode AE3 may be spaced apart from each other on the second passivation layer PAS2, respectively. It has been illustrated in FIG. 6 that the first to third pixel electrodes AE1, AE2, and AE3 are spaced apart from each other in the fourth direction DR4.

The pixel electrodes AE1, AE2, and AE3 may be electrically connected to the drain electrodes DE of the thin film transistors TFT through the first and second connection electrodes CNE1 and CNE2. Edges of the pixel electrodes AE1, AE2, and AE3 spaced apart from each other are covered by the pixel defining film PDL, such that the first to third pixel electrodes AE1, AE2, and AE3 may be insulated from each other.

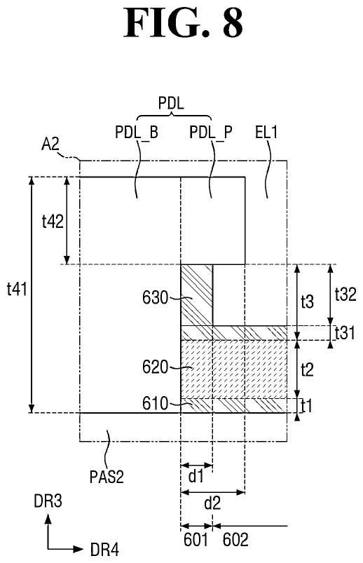

FIG. 8 is an enlarged view illustrating area A2 of FIG. 7. Area A2 relates to a boundary between the first pixel electrode AE1 and the pixel defining film PDL.

The pixel defining film PDL may be disposed on the second passivation layer PAS2 and the pixel electrodes AE1, AE2, and AE3. The pixel defining film PDL is entirely disposed on the second passivation layer PAS2, but exposes portions of upper surfaces of the first to third pixel electrodes AE1, AE2, and AE3 to define the emission areas EA1, EA2, and EA3. In an embodiment, the pixel defining film PDL may expose the first pixel electrode AE1 in the first emission area EA1, and a first light-emitting layer EL1 may be directly disposed on the first pixel electrode AE1, for example. The pixel defining film PDL may cover edges of the upper surfaces and side surfaces of the pixel electrodes AE1, AE2, and AE3.

The pixel defining film PDL may include a body portion PDL_B and a protrusion portion PDL_P protruding from the body portion PDL_B toward each of the emission areas EA1, EA2, and EA3. The protrusion portion PDL_P may be a portion of a side surface of the body portion PDL_B protruding toward each of the emission areas EA1, EA2, and EA3. A thickness t42 of the protrusion portion PDL_P may be smaller than a thickness t41 of the body portion PDL_B. A width d2 of the protrusion portion PDL_P is defined as a length of the protrusion portion PDL_P protruding from the body portion PDL_B. The protrusion portion PDL_P may be disposed on an edge portion 601 of each of the pixel electrodes AE1, AE2, and AE3.

The pixel defining film PDL may include an inorganic insulating material. The pixel defining film PDL may include at least one of a silicon nitride layer, a silicon oxynitride layer, a silicon oxide layer, a titanium oxide layer, an aluminum oxide layer, a tantalum oxide layer, a hafnium oxide layer, a zinc oxide layer, and an amorphous silicon layer, but is not limited thereto.

Each of the pixel electrodes AE1, AE2, and AE3 include a main portion 602 and an edge portion 601 surrounding the main portion 602. The main portion 602 may be an area including the center of each of the pixel electrodes AE1, AE2, and AE3 and the periphery of the center, and may be a flat portion having a constant thickness. The edge portion 601 may be an edge area of each of the pixel electrodes AE1, AE2, and AE3. Only a case where a boundary between the edge portion 601 and the main portion 602 is right-angled has been illustrated in FIGS. 6 and 8, but the boundary between the edge portion 601 and the main portion 602 may be rounded.

A thickness (t1+t2+t3) of the edge portion 601 may be greater than a thickness (t1+t2+t31) of the main portion 602. In this case, in the thickness of the edge portion 601 and the thickness of the main portion 602, a thickness of a portion of the pixel electrode penetrating through the second passivation layer PAS2 and connected to the second connection electrode CNE2 is not considered, and a thickness from an upper surface of the second passivation layer PAS2 is considered.

When the pixel electrodes AE1, AE2, and AE3 support the pixel defining film PDL in a state in which they have a relatively great thickness at the edge portions 601, it is possible to prevent a decrease in work function and deterioration in hole injection capability without separate protective layers. Since the separate protective layers are not included between the pixel electrodes AE1, AE2, and AE3 and the pixel defining film PDL, processes for fabrication of the display device may be simplified, and the occurrence of a mura due to the protective layers may be prevented.

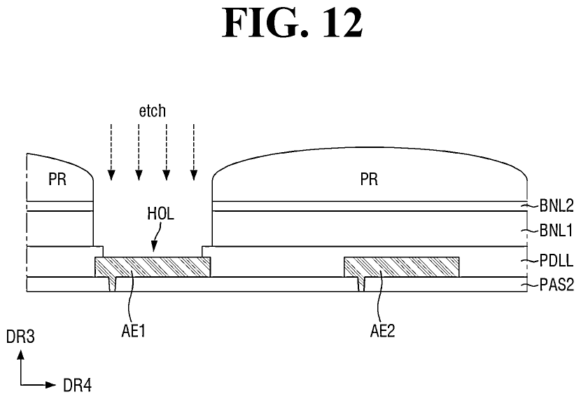

During a dry etching process of defining holes HOL (refer to FIG. 12) penetrating through the first and second bank layers BN1 and BN2, upper surfaces of the pixel electrodes AE1, AE2, and AE3 that are not covered with the pixel defining film PDL may be exposed to plasma. A work function of the pixel electrodes AE1, AE2, and AE3 in areas exposed to the plasma decreases, and hole injection capability of the pixel electrodes AE1, AE2, and AE3 in the areas exposed to the plasma deteriorates. It is possible to remove the pixel electrodes AE1, AE2, and AE3 of the areas damaged due to the exposure to the plasma while forming undercut structures of the first bank layer BN1 through a subsequent wet etching process. Upper portions of the pixel electrodes AE1, AE2, and AE3 corresponding to the main portions 602 exposed without being covered with the pixel defining film PDL may be removed by a partial thickness, and the edge portions 601 of the pixel electrodes AE1, AE2, and AE3 disposed under the protrusion portions PDL_P of the pixel defining film PDL may not be etched. Accordingly, the thickness (t1+t2+t3) of the edge portion 601 may be greater than the thickness (t1+t2+t31) of the main portion 602. In addition, the pixel electrodes AE1, AE2, and AE3 in the areas in which the work function decreases and the hole injection capability deteriorates are removed, such that the entirety of the hole injection capability of the pixel electrodes AE1, AE2, and AE3 may be maintained.

When portions of the pixel electrodes AE1, AE2, and AE3 are etched by isotropic wet etching, the pixel electrodes AE1, AE2, and AE3 may be etched even in areas covered with the pixel defining film PDL. Accordingly, the width d2 of the protrusion portion PDL_P of the pixel defining film PDL may be greater than a width d1 of the edge portion 601 of each of the pixel electrodes AE1, AE2, and AE3.

The protrusion portions PDL_P of the pixel defining film PDL may be disposed on portions of the main portions 602 of the pixel electrodes AE1, AE2, and AE3 as well as on the edge portions 601 of the pixel electrodes AE1, AE2, and AE3. Spaces may be formed between the protrusion portions PDL_P of the pixel defining film PDL and the main portions 602 of the pixel electrodes AE1, AE2, and AE3, and light-emitting layers EL1, EL2, and EL3 to be described later may be filled in these spaces. Lower surfaces of the protrusion portions PDL_P of the pixel defining film PDL may contact the edge portions 601 of the pixel electrodes AE1, AE2, and AE3 and portions of the light-emitting layers EL1, EL2, and EL3.

Exposed side surfaces of the body portions PDL_B of the pixel defining film PDL may contact side surfaces, specifically, outer side surfaces of the edge portions 601, of the pixel electrodes AE1, AE2, and AE3.

A difference (t32) between the thickness (t1+t2+t3) of the edge portion 601 and the thickness (t1+t2+t31) of the main portion of each of the pixel electrodes AE1, AE2, and AE3 may be about 150 Å to about 300 Å. The difference (t32) between the thickness (t1+t2+t3) of the edge portion 601 and the thickness (t1+t2+t31) of the main portion of each of the pixel electrodes AE1, AE2, and AE3 corresponds to a thickness of each of the pixel electrodes AE1, AE2, and AE3 removed by the isotropic wet etching.

The pixel electrodes AE1, AE2, and AE3 may include a transparent electrode material and a conductive metal material. The conductive metal material may be one or more of silver (Ag), copper (Cu), aluminum (Al), nickel (Ni), and lanthanum (La). The transparent electrode material may be one or more of indium tin oxide (“ITO”), indium zinc oxide (“IZO”), and indium tin zinc oxide (“ITZO”).

Each of the pixel electrodes AE1, AE2, and AE3 may have a multilayer structure. Each of the pixel electrodes AE1, AE2, and AE3 may have a structure of three or more layers in which a lower transparent electrode layer 610, a metal electrode layer 620, and an upper transparent electrode layer 630 are sequentially stacked. In an embodiment, the lower transparent electrode layer 610 and the upper transparent electrode layer 630 may include ITO, and the metal electrode layer 620 may include silver (Ag).

The lower transparent electrode layer 610 and the metal electrode layer 620 may be flat in the main portion 602 and the edge portion 601. That is, the lower transparent electrode layer 610 may have the same thickness in the main portion 602 and the edge portion 601. Similarly, the metal electrode layer 620 may also have the same thickness in the main portion 602 and the edge portion 601.

In an embodiment, a thickness t1 of the lower transparent electrode layer 610 may be about 30 Å to about 100 Å. The metal electrode layer 620 should reflect light emitted from each of the light-emitting layers EL1, EL2, and EL3, and may thus be relatively thicker than the lower transparent electrode layer 610. A thickness of the metal electrode layer 620 may be about 700 Å to about 1000 Å.

The upper transparent electrode layer 630 may have different thicknesses in the main portion 602 and the edge portion 601. A thickness t3 of the edge portion 601 of the upper transparent electrode layer 630 may be greater than a thickness t31 of the main portion 602 of the upper transparent electrode layer 630. That is, the difference (t32) between the thickness (t1+t2+t3) of the edge portion 601 and the thickness (t1+t2+t31) of the main portion of each of the pixel electrodes AE1, AE2, and AE3 may be formed in the upper transparent electrode layer 630.

When a transparent electrode is formed through a sputtering process under an atmosphere of a mixed gas of hydrogen gas and argon gas, a thickness of the electrode maintaining amorphous characteristics may be greater than when the transparent electrode is formed under an atmosphere of only argon gas. The edge portion 601 of the upper transparent electrode layer 630 is not etched, and may thus have the same thickness as each of the pixel electrodes AE1, AE2, and AE3 fabricated initially, and the thickness of the edge portion 601 of the upper transparent electrode layer 630 may be greater than that of the transparent electrode fabricated under the atmosphere of only argon gas.

In an embodiment, the thickness t3 of the edge portion 601 of the upper transparent electrode layer 630 may be about 400 Å to about 700 Å. The thickness t31 of the main portion 602 of the upper transparent electrode layer 630 may be about 100 Å to about 500 Å.

The lower transparent electrode layer 610 and the upper transparent electrode layer 630 may be crystalline. The lower transparent electrode layer 610 and the upper transparent electrode layer 630 may include or consist of an amorphous material including hydrogen therein, and be then crystallized by removing hydrogen through heat treatment.

The light-emitting layers EL1, EL2, and EL3 may be disposed on the pixel electrodes AE1, AE2, and AE3, respectively. The light-emitting layers EL1, EL2, and EL3 may be organic light-emitting layers including an organic material, and may be formed on the pixel electrodes AE1, AE2, and AE3, respectively, through a deposition process. When the thin film transistors TFT apply predetermined voltages to the pixel electrodes AE1, AE2, and AE3 of the light-emitting elements ED1, ED2, and ED3 and the common electrodes CE1, CE2, and CE3 of the light-emitting elements ED1, ED2, and ED3 receives a common voltage or a cathode voltage, holes and electrons may move to the light-emitting layers EL1, EL2, and EL3 through hole transporting layers and electron transporting layers, respectively, and may be combined with each other in the light-emitting layers EL1, EL2, and EL3 to emit light.

The light-emitting layers EL1, EL2, and EL3 may include a first light-emitting layer EL1, a second light-emitting layer EL2, and a third light-emitting layer EL3 each disposed in the different emission areas EA1, EA2, and EA3. The first light-emitting layer EL1 may be disposed on the first pixel electrode AE1 in the first emission area EA1, the second light-emitting layer EL2 may be disposed on the second pixel electrode AE2 in the second emission area EA2, and the third light-emitting layer EL3 may be disposed on the third pixel electrode AE3 in the third emission area EA3. The first to third light-emitting layers EL1, EL2, and EL3 may be light-emitting layers of the first to third light-emitting elements ED1, ED2 and ED3, respectively. The first light-emitting layer EL1 may be a light-emitting layer emitting red light, which is light of a first color, the second light-emitting layer EL2 may be a light-emitting layer emitting green light, which is light of a second color, and the third light-emitting layer EL3 may be a light-emitting layer emitting blue light, which is light of a third color.

The deposition process of the light-emitting layers EL1, EL2, and EL3 may be performed so that electrode materials are deposited in a direction inclined with respect to an upper surface of the substrate SUB rather than a direction perpendicular to the upper surface of the substrate SUB. Accordingly, the light-emitting layers EL1, EL2, and EL3 may be disposed on the upper surfaces of the pixel electrodes AE1, AE2, and AE3 exposed through the openings, respectively, and may be disposed to fill the spaces between the main portions 602 of the pixel electrodes AE1, AE2, and AE3, and the protrusion portions PDL_P of the pixel defining film PDL.

The common electrodes CE1, CE2, and CE3 may be disposed on the light-emitting layers EL1, EL2, and EL3, respectively. The common electrodes CE1, CE2, and CE3 may include a transparent conductive material to emit the light generated from the light-emitting layers EL1, EL2, and EL3. The common electrodes CE1, CE2, and CE3 may receive a common voltage or a relatively low potential voltage. When the pixel electrodes AE1, AE2, and AE3 receive voltages corresponding to data voltages and the common electrodes CE1, CE2, and CE3 receive the relatively low potential voltage, potential differences are formed between the pixel electrodes AE1, AE2, and AE3 and the common electrodes CE1, CE2, and CE3, such that the light-emitting layers EL1, EL2, and EL3 may emit the light.

The common electrodes CE1, CE2, and CE3 may include a first common electrode CE1, a second common electrode CE2, and a third common electrode CE3 each disposed in the different emission areas EA1, EA2, and EA3. The first common electrode CE1 may be disposed on the first light-emitting layer EL1 in the first emission area EA1, the second common electrode CE2 may be disposed on the second light-emitting layer EL2 in the second emission area EA2, and the third common electrode CE3 may be disposed on the third light-emitting layer EL3 in the third emission area EA3. The first to third common electrodes CE1, CE2, and CE3 may be spaced apart from each other.

The common electrodes CE1, CE2, and CE3 may be formed through a deposition process, similar to the light-emitting layers EL1, EL2, and EL3. The deposition process of the common electrodes CE1, CE2, and CE3 may be performed so that electrode materials are deposited in the direction inclined with respect to the upper surface of the substrate SUB rather than the direction perpendicular to the upper surface of the substrate SUB.

The capping layers CAP may be disposed on the common electrodes CE1, CE2, and CE3. The capping layers CAP may include an organic or inorganic insulating material and cover patterns disposed on the light-emitting elements ED1, ED2, and ED3. The capping layers CAP may prevent the light-emitting elements ED1, ED2, and ED3 from being damaged by external air. In an embodiment, the capping layer CAP may include an organic material such as α-NPD, NPB, TPD, m-MTDATA, Alq₃, LiF, and/or CuPc, or an inorganic material such as aluminum oxide, titanium oxide, tantalum oxide, hafnium oxide, zinc oxide, silicon oxide, silicon nitride, and/or silicon oxynitride.

The display device 10 may include a plurality of bank structures BNS disposed on the pixel defining film PDL. The bank structure BNS may have a structure in which bank layers BN1 and BN2 including different materials are sequentially stacked, may define the plurality of openings including the emission areas EA1, EA2, and EA3, and may be disposed so as to overlap a light-blocking layer BM to be described later. The light-emitting elements ED1, ED2, and ED3 of the display device 10 may overlap the openings of the bank structure BNS.

The bank structure BNS may include a first bank layer BN1 disposed on the pixel defining film PDL and a second bank layer BN2 disposed on the first bank layer BN1.

The first bank layer BN1 may be disposed on the pixel defining film PDL. Side surfaces of the first bank layer BN1 may be depressed further than side surfaces of the pixel defining film PDL in a direction opposite to a direction toward the emission areas EA1, EA2, and EA3. The side surfaces of the first bank layer BN1 may be depressed further than side surfaces of a second bank layer BN2 to be described later in the direction opposite to the direction toward the emission areas EA1, EA2, and EA3.

In an embodiment, the first bank layer BN1 may include a metal material. The metal material of the first bank layer BN1 may be any material that is removed together with the second bank layer BN2 by dry etching, but is capable of forming an undercut structure by showing an etch rate different from that of the second bank layer BN2 with respect to wet etching by an alkali-based etchant. In an embodiment, the first bank layer BN1 may include aluminum (Al).

In an embodiment, a thickness of the first bank layer BN1 may be in the range of about 4,000 Å to about 10,000 Å. When the thickness of the first bank layer BN1 is in the above range, the light-emitting layers EL1, EL2, and EL3 and the common electrodes CE1, CE2, and CE3 separated from each other may be formed through deposition and etching processes rather than a mask process.

In an embodiment, the common electrodes CE1, CE2, and CE3 may be in direct contact with the side surfaces of the first bank layer BN1. The common electrodes CE1, CE2, and CE3 of different light-emitting elements ED1, ED2, and ED3 may be in direct contact with the first bank layer BN1, respectively, and the first bank layer BN1 may include the metal material, such that the common electrodes CE1, CE2, and CE3 may be electrically connected to each other through the first bank layer BN1.

The light-emitting layers EL1, EL2, and EL3 may be in direct contact with the side surfaces of the first bank layer BN1. A contact area between the common electrodes CE1, CE2, and CE3 and the side surfaces of the first bank layer BN1 may be greater than a contact area between the light-emitting layers EL1, EL2, and EL3 and the side surfaces of the first bank layer BN1. The common electrodes CE1, CE2, and CE3 may be disposed to have a greater area than the light-emitting layers EL1, EL2, and EL3 on the side surfaces of the first bank layer BN1 or may be disposed up to a greater height than the light-emitting layers EL1, EL2, and EL3 on the side surfaces of the first bank layer BN1. Since the common electrodes CE1, CE2, and CE3 of the different light-emitting elements ED1, ED2, and ED3 are electrically connected to each other through the first bank layer BN1, it may be advantageous that the common electrodes CE1, CE2, and CE3 contact the first bank layer BN1 in a greater area. Although not illustrated in FIGS. 6 and 7, the light-emitting layers EL1, EL2, and EL3 may be in direct contact with the side surfaces of the first bank layer BN1.

The second bank layer BN2 may be disposed on the first bank layer BN1. The second bank layer BN2 may include tips TIP, which are areas protruding further than the first bank layer BN1. The side surfaces of the second bank layer BN2 may protrude further than the side surfaces of the first bank layer BN1 toward the emission areas EA1, EA2, and EA3.

The side surfaces of the second bank layer BN2 have a shape in which they protrude further than the side surfaces of the first bank layer BN1 toward the emission areas EA1, EA2, and EA3, and accordingly, undercut structures of the first bank layer BN1 may be formed under the tips TIP of the second bank layer BN2. The second bank layer BN2 includes the tips TIP, and thus, the light-emitting elements ED1, ED2, and ED3 separated from each other may be formed without a mask process.

Shapes of the side surfaces of the first and second bank layers BN1 and BN2 may be structures formed due to a difference in etch rate in an etching process because the first bank layer BN1 and the second bank layer BN2 include the different materials from each other. In an embodiment, the second bank layer BN2 may include a material having an etch rate slower than that of the first bank layer BN1, and the first bank layer BN1 may be further etched in the etching process, such that undercuts may be formed under the tips TIP of the second bank layer BN2. In an embodiment, the second bank layer BN2 may include titanium (Ti).

In processes for fabrication of the display device 10, a mask process is desired in order to form the light-emitting layers EL1, EL2, and EL3 of the light-emitting elements ED1, ED2, and ED3 for each of the emission areas EA1, EA2, and EA3. A structure for mounting a mask in order to perform the mask process or an unnecessarily great area of the non-display area NDA may be desired in the display device 10 in order to control dispersion according to the mask process. When such a mask process is minimized, an unnecessary component such as the structure for mounting the mask may be omitted from the display device 10, and the area of the non-display area NDA for controlling the dispersion may be minimized.

In the display device 10 in an embodiment, the bank structure BNS includes the tips TIP protruding toward the emission areas EA1, EA2, and EA3, and thus, the light-emitting layers EL1, EL2, and EL3 and the common electrodes CE1, CE2, and CE3 may be formed through deposition and etching processes rather than the mask process. In addition, it is possible to form different layers individually in the different emission areas EA1, EA2, and EA3 even through a deposition process. In an embodiment, even though the light-emitting layers EL1, EL2, and EL3 and the common electrodes CE1, CE2, and CE3 of the light-emitting elements ED1, ED2, and ED3 are formed through a deposition process that does not use the mask, deposited materials may be disconnected from each other with the bank structure BNS interposed therebetween by the tips TIP of the second bank layer BN2 rather than being connected to each other between the emission areas EA1, EA2, and EA3, for example. It is possible to form the different layers individually in the different emission areas EA1, EA2, and EA3 through a process of forming a material for forming a predetermined layer on the entirety of the surface of the display device 10 and then etching and removing a layer formed in unwanted areas. In the display device 10, through the deposition and etching processes without using the mask process, the different light-emitting elements ED1, ED2, and ED3 may be formed for each of the emission areas EA1, EA2, and EA3, the unnecessary component may be omitted from the display device 10, and the area of the non-display area NDA may be minimized.

In an embodiment, a thickness of the second bank layer BN2 may be in the range of about 500 Å to about 3,000 Å. In an embodiment, the tips TIP of the second bank layer BN2 protruding from the first bank layer BN1 toward the emission areas EA1, EA2, and EA3 may have a width of about 0.1 micrometer (μm) to about 1.0 μm.

The tips TIP of the second bank layer BN2 may overlap the common electrodes CE1, CE2, and CE3 in the thickness direction DR3 of the substrate. In addition, the tips TIP of the second bank layer BN2 may overlap the light-emitting layers EL1, EL2, and EL3 in a direction DR3 perpendicular to the substrate. In addition, the tips TIP of the second bank layer BN2 may overlap the pixel defining film PDL in the direction DR3 perpendicular to the substrate. The common electrodes CE1, CE2, and CE3 may be formed under lower surfaces of the tips TIP of the second bank layer BN2. A maximum distance from the substrate SUB to each of the common electrodes CE1, CE2, and CE3 may be smaller than a maximum distance from the substrate SUB to the second bank layer BN2.

In an embodiment, a width at which a side surface of the protrusion portion PDL_P of the pixel defining film PDL protrudes further than the side surface of the first bank layer BN1 may be greater than a width (i.e., a width of the tip TIP) at which the side surface of the second bank layer BN2 protrudes further than the side surface of the first bank layer BN1.

The display device 10 may include the trace patterns TRP1, TRP2, and TRP3 that are traces of the deposition process on the bank structure BNS. The trace patterns TRP1, TRP2, and TRP3 may include organic patterns ELP1, ELP2, and ELP3, electrode patterns CEP1, CEP2, and CEP3, and capping patterns CLP, respectively, and may have a shape in which they surround contours of the emission areas EA1, EA2, and EA3 on the second bank layer BN2. The organic patterns ELP1, ELP2, and ELP3, the electrode patterns CEP1, CEP2, and CEP3, and the capping patterns CLP may be formed simultaneously with the light-emitting layers EL1, EL2, and EL3 and the common electrodes CE1, CE2, and CE3 of the light-emitting elements ED1, ED2, and ED3 and the capping layers CAP when the light-emitting layers EL1, EL2, and EL3 and the common electrodes CE1, CE2, and CE3 of the light-emitting elements ED1, ED2, and ED3 and the capping layers CAP are formed.

Such trace patterns TRP1, TRP2, and TRP3 may be traces formed while the deposited materials are disconnected from the light-emitting layers EL1, EL2, and EL3, the common electrodes CE1, CE2, and CE3, and the capping layers CAP within the emission areas EA1, EA2, and EA3 rather than being connected to the light-emitting layers EL1, EL2, and EL3, the common electrodes CE1, CE2, and CE3, and the capping layers CAP within the emission areas EA1, EA2, and EA3 because the bank structure BNS includes the tips TIP. The light-emitting layers EL1, EL2, and EL3, the common electrodes CE1, CE2, and CE3, and the capping layers CAP may be formed within the openings, the organic patterns ELP1, ELP2, and ELP3 and the light-emitting layers EL1, EL2, and EL3 may be disconnected from each other by the tips TIP of the bank structure BNS, the electrode patterns CEP1, CEP2, and CEP3 and the common electrodes CE1, CE2, and CE3 may be disconnected from each other by the tips TIP of the bank structure BNS, and the capping patterns CLP and the capping layers CAP may be disconnected from each other by the tips TIP of the bank structure BNS. The trace patterns TRP1, TRP2, and TRP3 may be formed by performing patterning around the respective emission areas EA1, EA2, and EA3 or the openings.

The display device 10 in an embodiment may include a plurality of organic patterns ELP1, ELP2, and ELP3 including the same materials as those of the light-emitting layers EL1, EL2, and EL3 and disposed on the bank structure BNS. Since the light-emitting layers EL1, EL2, and EL3 are formed through a process of depositing materials on the entirety of the surface of the display device 10, the materials forming the light-emitting layers EL1, EL2, and EL3 may be deposited on the bank structure BNS as well as in the emission areas EA1, EA2, and EA3.

In an embodiment, the display device 10 may include the organic patterns ELP1, ELP2, and ELP3 disposed above the bank structure BNS, for example. The organic patterns ELP1, ELP2, and ELP3 may include a first organic pattern ELP1, a second organic pattern ELP2, and a third organic pattern ELP3 disposed on the second bank layer BN2 of the bank structure BNS.

The first organic pattern ELP1 may include the same material as that of the first light-emitting layer EL1 of the first light-emitting element ED1. The second organic pattern ELP2 may include the same material as that of the second light-emitting layer EL2 of the second light-emitting element ED2, and the third organic pattern ELP3 may include the same material as that of the third light-emitting layer EL3 of the third light-emitting element ED3. The organic patterns ELP1, ELP2, and ELP3 may be formed in processes of forming the light-emitting layers EL1, EL2, and EL3 including the same materials as those of the organic patterns ELP1, ELP2, and ELP3, respectively. The organic patterns ELP1, ELP2, and ELP3 may be disposed adjacent to the emission areas EA1, EA2, and EA3 in which the respective light-emitting layers EL1, EL2, and EL3 are disposed.

The display device 10 in an embodiment may include a plurality of electrode patterns CEP1, CEP2, and CEP3 including the same materials as those of the common electrodes CE1, CE2, and CE3 and disposed on the bank structure BNS. A first electrode pattern CEP1, a second electrode pattern CEP2, and a third electrode pattern CEP3 may be directly disposed on the first organic pattern ELP1, the second organic pattern ELP2, and the third organic pattern ELP3, respectively. An arrangement relationship between the electrode patterns CEP1, CEP2, and CEP3 and the organic patterns ELP1, ELP2, and ELP3 may be the same as an arrangement relationship between the light-emitting layers EL1, EL2, and EL3 and the common electrodes CE1, CE2, and CE3 of the light-emitting elements ED1, ED2, and ED3.

The display device 10 may include the capping patterns CLP disposed above the bank structure BNS. The capping patterns CLP may be directly disposed on the first electrode pattern CEP1, the second electrode pattern CEP2, and the third electrode pattern CEP3 disposed on the second bank layer BN2 of the bank structure BNS. An arrangement relationship between the capping patterns CLP and the electrode patterns CEP1, CEP2, and CEP3 may be the same as an arrangement relationship between the common electrodes CE1, CE2, and CE3 of the light-emitting elements ED1, ED2, and ED3 and the capping layers CAP.

The plurality of organic patterns ELP1, ELP2, and ELP3, the electrode patterns CEP1, CEP2, and CEP3, and the capping patterns CLP may be disposed on the bank structure BNS, and may be disposed to surround the emission areas EA1, EA2, and EA3 or the openings. Stacked structures of the organic patterns ELP1, ELP2, and ELP3, the electrode patterns CEP1, CEP2, and CEP3, and the capping patterns CLP disposed around the emission areas EA1, EA2, and EA3 may be partially etched in the processes for fabrication of the display device 10, such that pattern shapes may be changed. Accordingly, portions of an upper surface of the second bank layer BN2 of the bank structure BNS may not be covered by the organic patterns ELP1, ELP2, and ELP3, the electrode patterns CEP1, CEP2, and CEP3, and the capping patterns CLP.

The thin film encapsulation layer TFEL may be disposed on the light-emitting elements ED1, ED2, and ED3 and the bank structure BNS, and may cover the plurality of light-emitting elements ED1, ED2, and ED3 and the bank structure BNS. The thin film encapsulation layer TFEL may include at least one inorganic film to prevent oxygen or moisture from permeating into the light-emitting element layer EML. The thin film encapsulation layer TFEL may include at least one organic film to protect the light-emitting element layer EML from foreign substances such as dust.

In an embodiment, the thin film encapsulation layer TFEL may include a first inorganic encapsulation film TFE1, an organic encapsulation film TFE2, and a second inorganic encapsulation film TFE3 that are sequentially stacked.

Each of the first inorganic encapsulation film TFE1 and the second inorganic encapsulation film TFE3 may include one or more inorganic insulating materials. The inorganic insulating material may be any one of silicon oxide, silicon nitride, and silicon oxynitride, and may be, e.g., aluminum oxide, titanium oxide, tantalum oxide, hafnium oxide, zinc oxide, silicon oxide, silicon nitride, and/or silicon oxynitride.

The organic encapsulation film TFE2 may include a polymer-based material. The polymer-based material may include an acrylic resin, an epoxy-based resin, polyimide, polyethylene, or the like. In an embodiment, the organic encapsulation film TFE2 may include an acrylic resin such as polymethyl methacrylate or polyacrylic acid, for example. The organic encapsulation film TFE2 may be formed by curing a monomer or applying a polymer.

The first inorganic encapsulation film TFE1 may be disposed on the light-emitting elements ED1, ED2, and ED3, a plurality of patterns, and the bank structure BNS. The first inorganic encapsulation film TFE1 may include a first inorganic layer TL1, a second inorganic layer TL2, and a third inorganic layer TL3 disposed to each correspond to the different emission areas EA1, EA2, and EA3. The first inorganic layer TL1, the second inorganic layer TL2, and the third inorganic layer TL3 may include an inorganic insulating material and cover the light-emitting elements ED1, ED2, and ED3, respectively. The first inorganic layer TL1, the second inorganic layer TL2, and the third inorganic layer TL3 may prevent the light-emitting elements ED1, ED2, and ED3 from being damaged by external air. The first inorganic layer TL1, the second inorganic layer TL2, and the third inorganic layer TL3 may be disposed to cover the organic patterns ELP1, ELP2, and ELP3, the electrode patterns CEP1, CEP2, and CEP3, and the capping patterns CLP to prevent the patterns disposed on the bank structure BNS from being peeled off during the processes for fabrication of the display device 10.

The first inorganic layer TL1, the second inorganic layer TL2, and the third inorganic layer TL3 may be formed through chemical vapor deposition (“CVD”), and may thus be formed along steps of layers on which they are deposited. In an embodiment, the first inorganic layer TL1, the second inorganic layer TL2, and the third inorganic layer TL3 may form thin films even under the undercuts by the tips TIP of the bank structure BNS, for example.

The first inorganic layer TL1 may be disposed on the first light-emitting element ED1 and the first electrode pattern CEP1. The first inorganic layer TL1 may be disposed along the first light-emitting element ED1, the capping layer CAP, and side surfaces of the second bank layer BN2 adjacent to the first common electrode CE1 so as to cover the first light-emitting element ED1, the capping layer CAP, and the side surfaces of the second bank layer BN2 adjacent to the first common electrode CE1, and may also be disposed to cover the first organic pattern ELP1, the first electrode pattern CEP1, and the capping pattern CLP. However, the first inorganic layer TL1 may not overlap a second opening and a third opening, and may be disposed only in a first opening and on the bank structure BNS around the first opening. It has been illustrated in FIGS. 6 and 7 that the first inorganic layer TL1 seals a first trace pattern TRP1 and the light-emitting element ED1 along outer surfaces of the first trace pattern TRP1 and the light-emitting element ED1 at a non-uniform thickness, but the first inorganic layer TL1 may be disposed along an upper surface and side surfaces of the first trace pattern TRP1, side surfaces and a lower surface of the second bank layer BN2, side surfaces of the first bank layer BN1, and an upper surface of the first common electrode CE1 at a uniform thickness.

The second inorganic layer TL2 may be disposed on the second light-emitting element ED2 and the second electrode pattern CEP2. However, the second inorganic layer TL2 may not overlap the first opening and the third opening, and may be disposed only in the second opening and on the bank structure BNS around the second opening.

The third inorganic layer TL3 may be disposed on the third light-emitting element ED3 and the third electrode pattern CEP3. However, the third inorganic layer TL3 may not overlap the first opening and the second opening, and may be disposed only in the third opening and on the bank structure BNS around the third opening.

The first inorganic layer TL1 may be formed after the first common electrode CE1 is formed, the second inorganic layer TL2 may be formed after the second common electrode CE2 is formed, and the third inorganic layer TL3 may be formed after the third common electrode CE3 is formed. Accordingly, the first to third inorganic layers TL1, TL2, and TL3 may be disposed to cover different electrode patterns CEP1, CEP2, and CEP3 and organic patterns ELP1, ELP2, and ELP3, respectively. In the plan view of FIG. 5, the first inorganic layer TL1, the second inorganic layer TL2, and the third inorganic layer TL3 may have the same areas as the first to third trace patterns TRP1, TRP2, and TRP3, respectively, and may have greater areas than the openings of the bank structure BNS or the emission areas EA1, EA2, and EA3, respectively. The first inorganic layer TL1, the second inorganic layer TL2, and the third inorganic layer TL3 may be spaced apart from each other on the bank structure BNS. Accordingly, portions of the second bank layer BN2 may not overlap the first to third inorganic layers TL1, TL2, and TL3, and portions of the upper surface of the second bank layer BN2 may be exposed without being covered by the first to third inorganic layers TL1, TL2, and TL3 in spaces between the first to third inorganic layers TL1, TL2, and TL3 spaced apart from each other. The exposed upper surface of the second bank layer BN2 may be in direct contact with the organic encapsulation film TFE2 of the thin film encapsulation layer TFEL.

The light-blocking layer BM may be disposed on the thin film encapsulation layer TFEL. The light-blocking layer BM may define a plurality of holes OPT1, OPT2, and OPT3 disposed to overlap the emission areas EA1, EA2, and EA3. In an embodiment, a first hole OPT1 may overlap the first emission area EA1, for example. A second hole OPT2 may overlap the second emission area EA2, and a third hole OPT3 may overlap the third emission area EA3. An area or a size of each of the holes OPT1, OPT2, and OPT3 may be greater than the area or the size of each of the emission areas EA1, EA2, and EA3. The holes OPT1, OPT2, and OPT3 of the light-blocking layer BM are greater than the emission areas EA1, EA2, and EA3, and accordingly, the light emitted from the emission areas EA1, EA2, and EA3 may be viewed by a user not only from a front surface but also from side surfaces of the display device 10.

The light-blocking layer BM may include a light absorbing material. In an embodiment, the light-blocking layer BM may include an inorganic black pigment or an organic black pigment, for example. The inorganic black pigment may be carbon black, and the organic black pigment may include at least one of lactam black, perylene black, and aniline black, but the disclosure is not limited thereto. The light-blocking layer BM may prevent color mixing due to permeation of visible light between the first to third emission areas EA1, EA2, and EA3 to improve a color gamut of the display device 10.

The display device 10 may include a plurality of color filters CF1, CF2, and CF3 disposed on the emission areas EA1, EA2, and EA3. The plurality of color filters CF1, CF2, and CF3 may be disposed to correspond to the emission areas EA1, EA2, and EA3, respectively. In an embodiment, the color filters CF1, CF2, and CF3 may be disposed on the light-blocking layer BM defining the plurality of holes OPT1, OPT2, and OPT3 disposed to correspond to the emission areas EA1, EA2, and EA3, for example. The holes of the light-blocking layer may overlap the emission areas EA1, EA2, and EA3 or the openings of the bank structures BNS, and may define light-emitting areas through which the light emitted from the emission areas EA1, EA2, and EA3 is emitted. Each of the color filters CF1, CF2, and CF3 may have a greater area than each of the holes of the light-blocking layer BM, and may completely cover the light-emitting area formed by each of the holes.

The color filters CF1, CF2, and CF3 may include a first color filter CF1, a second color filter CF2, and a third color filter CF3 disposed to each correspond to the different emission areas EA1, EA2, and EA3. The color filters CF1, CF2, and CF3 may include colorants such as dyes or pigments absorbing light of wavelength bands other than light of a predetermined wavelength band, and may be disposed to correspond to the colors of the light-emitting from the emission areas EA1, EA2, and EA3. In an embodiment, the first color filter CF1 may be a red color filter disposed to overlap the first emission area EA1 and transmitting only the first light, which is the red light, therethrough, for example. The second color filter CF2 may be a green color filter disposed to overlap the second emission area EA2 and transmitting only the second light, which is the green light, therethrough, and the third color filter CF3 may be a blue color filter disposed to overlap the third emission area EA3 and transmitting only the third light, which is the blue light, therethrough.

The plurality of color filters CF1, CF2, and CF3 may be spaced apart from other adjacent color filters CF1, CF2, and CF3 on the light-blocking layer BM. The color filters CF1, CF2, and CF3 may have greater areas than the holes OPT1, OPT2, and OPT3 of the light-blocking layer BM while covering the holes OPT1, OPT2, and OPT3 of the light-blocking layer BM, respectively, but may have areas enough to be spaced apart from other color filters CF1, CF2, and CF3 on the light-blocking layer BM. However, the disclosure is not limited thereto. The plurality of color filters CF1, CF2, and CF3 may be disposed to partially overlap other adjacent color filters CF1, CF2, and CF3. Different color filters CF1, CF2, and CF3 may overlap each other on a light-blocking layer BM to be described later, which is an area that does not overlap the emission areas EA1, EA2, and EA3. In the display device 10, the color filters CF1, CF2, and CF3 are disposed to overlap each other, and accordingly, an intensity of reflected light by external light may be reduced. Furthermore, a color feeling of the reflected light by the external light may be controlled by adjusting an arrangement, shapes, areas, or the like, of the color filters CF1, CF2, and CF3 in a plan view.

The overcoat layer OC may be disposed on the color filters CF1, CF2, and CF3 to planarize upper ends of the color filters CF1, CF2, and CF3. The overcoat layer OC may be a colorless light-transmitting layer that does not have a color of a visible light band. In an embodiment, the overcoat layer OC may include a colorless light-transmitting organic material such as an acrylic resin, for example.

Hereinafter, processes for fabrication of the display device 10 in an embodiment will be described with reference to other drawings.

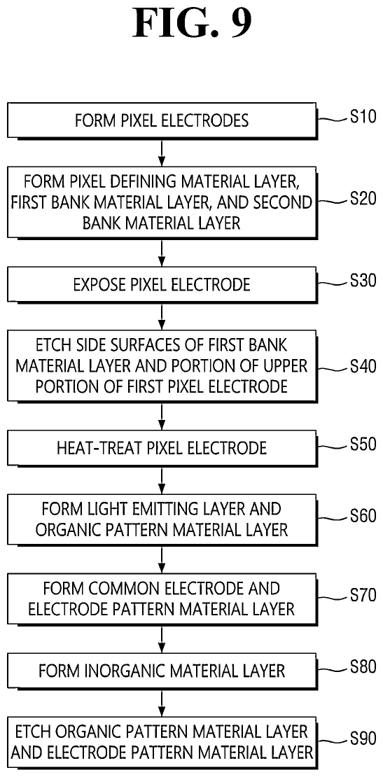

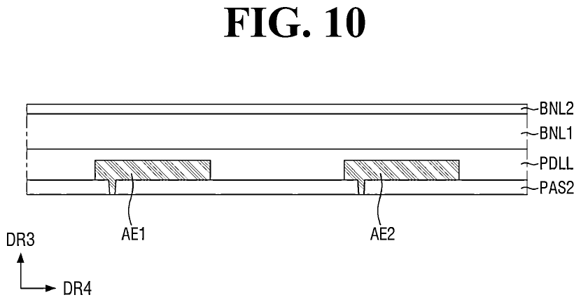

FIG. 9 is a flowchart illustrating an embodiment of processes for fabrication of the display device, and FIGS. 10 to 18 are detailed cross-sectional views sequentially illustrating an embodiment of the processes for fabrication of the display device.

In FIGS. 9 to 17, processes of forming the bank structure BNS and the light-emitting elements ED as the light-emitting element layer EML and the thin film encapsulation layer TFEL of the display device 10 are schematically illustrated. Hereinafter, a description of processes of forming respective layers among the processes for fabrication of the display device 10 will be omitted, and the order of forming the respective layers will be described.

Referring to FIG. 10, a plurality of pixel electrodes AE1, AE2, and AE3 spaced apart from each other, a pixel defining material layer PDLL, and a plurality of bank material layers BNL1 and BNL2 are formed on the thin film transistor layer TFTL.

Although not illustrated in FIG. 10, the thin film transistor layer TFTL may be disposed on the substrate SUB, and a structure of the thin film transistor TFTL is the same as that described above with reference to FIG. 6. A detailed description thereof will be omitted.

The plurality of pixel electrodes AE1, AE2, and AE3 spaced apart from each other are formed by entirely forming a pixel electrode material on the substrate and then patterning the pixel electrode material (operation S10). When the pixel electrodes are formed on the substrate, a sputtering process may be used.

The pixel electrodes AE1, AE2, and AE3 may have the multilayer structure, as described above. In an embodiment, the upper transparent electrode layer and the lower transparent electrode layer may include ITO. In a case where the upper transparent electrode layer 630 is formed through a

sputtering process under an atmosphere of a mixed gas including hydrogen and argon, it is possible to increase a thickness of an electrode while maintaining amorphous characteristics as compared with a case where the upper transparent electrode layer 630 is formed under an atmosphere of only argon gas. A thickness of an amorphous transparent electrode layer formed under the atmosphere of only argon gas may be about 150 Å or less, but a thickness of the amorphous transparent electrode layer formed under the atmosphere of the mixed gas including hydrogen and argon may be about 400 Å to about 700 Å. In an embodiment, the mixed gas may include a hydrogen gas at a concentration of about 0.1% to about 5.0%.

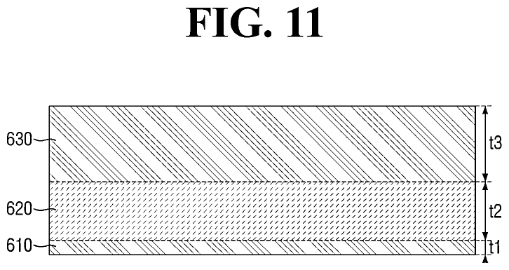

FIG. 11 illustrates a cross section of the first pixel electrode AE1 of the plurality of pixel electrodes that are formed, and a portion of the first pixel electrode AE1 penetrating through the second passivation layer PAS2 and connected to the second connection electrode CNE2 is omitted in FIG. 11. Referring to FIG. 11, it may be seen that the upper transparent electrode layer 630 has a constant thickness t3 and has a flat upper surface.

The pixel definition material layer PDLL and the bank material layers BNL1 and BNL2 may be disposed on the pixel electrodes AE1, AE2, and AE3 (operation S20). The pixel defining material layer PDLL may be disposed to cover an entirety of the thin film transistor layer TFTL, and first and second bank material layers BNL1 and BNL2 may be disposed to cover an entirety of the pixel defining material layer PDLL. The bank material layers BNL1 and BNL2 may be partially etched in a subsequent process to form the bank layers BN1 and BN2 of the bank structure BNS illustrated in FIG. 6, respectively.

Next, referring to FIG. 12, a photoresist PR is formed on the bank material layers BNL1 and BNL2, and a first etching process (1^{st} etching) of etching portions of the first and second bank material layers BNL1 and BNL2 and the pixel defining material layer PDLL using the photoresist PR as a mask is performed to define holes HOL1. The holes HOL may be defined in areas overlapping the plurality of pixel electrodes AEI, AE2, and AE3, and may define the openings of the bank structure BNS.

The photoresists PR may be spaced apart from each other on the bank material layers BNL1 and BNL2. The photoresists PR may be disposed on the second bank material layer BNL2 so as to expose a portion overlapping the first pixel electrode AE1.

In an embodiment, dry etching may be performed as the first etching process (1^{st} etching). The bank material layers BNL1 and BNL2 and the pixel defining material layer PDLL may be anisotropically etched, but due to a difference between materials of the bank material layers BNL1 and BNL2 and the pixel defining material layer PDLL, an etched area of the pixel defining material layer PDLL may be smaller than an etched area of the bank material layers BNL1 and BNL2. In the process, portions of upper surfaces of the pixel electrodes AE1, AE2, and AE3 may be exposed (operation S30). An upper surface of the first pixel electrode AE1 that is not covered by the pixel defining material layer PDLL is exposed to plasma, such that a work function decreases and hole injection capability deteriorates.

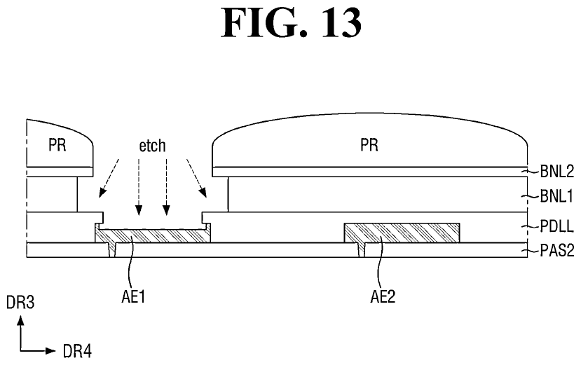

Next, referring to FIG. 13, a portion of an upper portion of the first pixel electrode AE1 is etched while undercut structures of the first bank material layer BNL1 are formed through a second etching process (2^{nd} etching) (operation S40). When separate protective layers are disposed on the pixel electrodes AE1, AE2, and AE3, an etching process for the undercut structures of the first bank material layer BNL1 and an etching process for removing the separate protective layers should be separately performed. When an amorphous transparent metal layer including hydrogen is formed to be thick, the formation of the undercut structures of the first bank material layer BNL1 and the removal of the first pixel electrode AE1 by a partial thickness may be simultaneously performed through one etching process. Accordingly, a process may be simplified without a separate protective layer.

In an embodiment, the second etching process may be isotropic wet etching.

The first bank material layer BNL1 may have a faster etch rate than the second bank material layer BNL2, and side surfaces of the second bank material layer BNL2 may be formed to protrude further than side surfaces of the first bank material layer BNL1. The side surfaces of the second bank material layer BNL2 protrude further than the side surfaces of the first bank material layer BNL1 toward the hole HOL to form tips TIP, and undercuts may be formed under the tips TIP.

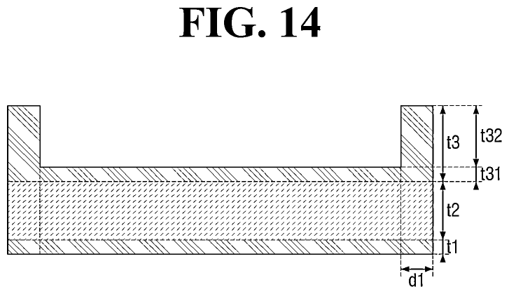

The first pixel electrode AE1 of an area damaged in the first etching process may be removed in the second etching process. The first pixel electrode AE1 may be removed by a thickness corresponding to the difference (t32) between the thickness (t1+t2+t3) of the edge portion 601 and the thickness (t1+t2+t31) of the main portion of each of the pixel electrodes AE1, AE2, and AE3. The first pixel electrode AE1 may also be etched in a partial area under the protrusion portion PDL_P of the pixel defining film PDL through the isotropic wet etching. FIG. 14 is a cross-section of the first pixel electrode AE1 after the second etching process, and the edge portion of the first pixel electrode AE1 has a greater thickness than the main portion of the first pixel electrode AE1. The width d1 of the edge portion 601 may be smaller than the width d2 of the protrusion portion PDL_P of the pixel defining film PDL.

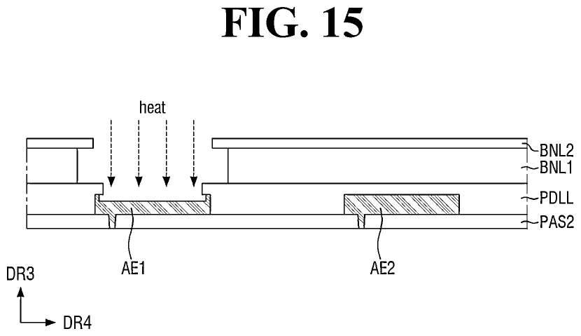

Subsequently, as illustrated in FIG. 15, the photoresist PR formed on the second bank material layer BNL2 is removed, and the exposed first pixel electrode AE1 is heat-treated (operation S50).

The amorphous first pixel electrode AE1 fabricated under the mixed gas including hydrogen may include hydrogen therein, and may then be crystallized by removing hydrogen included therein through a heat treatment process. After the heat treatment process, transmissivity of a transparent electrode layer may increase and predetermined resistance of the transparent electrode layer may decrease. In an embodiment, the heat treatment process may be performed at about 260 degrees Celsius (° C.) or less within about 2 hours.

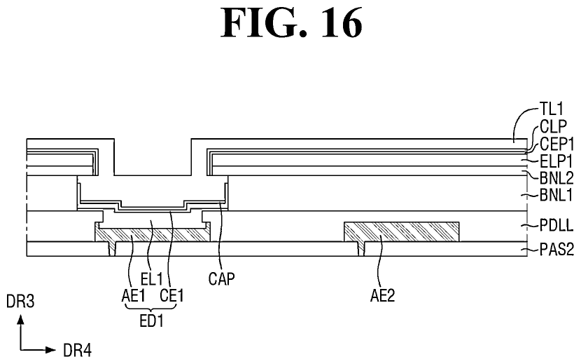

Next, referring to FIG. 16, the first light-emitting layer EL1, the first common electrode CE1, and the capping layer CAP are deposited on the first pixel electrode AE1 to form the first light-emitting element ED1. In this case, since the first light-emitting layer EL1, the first common electrode CE1, and the capping layer CAP are formed on the entirety of the surface of the bank structure BNS, the first light-emitting layer EL1, the first common electrode CE1, and the capping layer CAP are formed within an opening overlapping the second pixel electrode AE2 as well as the first pixel electrode AE1. Materials forming the first light-emitting layer EL1, the first common electrode CE1, and the capping layer CAP may also be formed on the second bank material layer BNL2 to form a trace pattern.

The first light-emitting layer EL1 and the first common electrode CE1 may be formed through deposition processes. The materials may not be smoothly deposited within the first opening due to the tips TIP of the second bank material layer BNL2. However, the materials of the first light-emitting layer EL1 and the first common electrode CE1 are deposited in the direction inclined with the upper surface of the substrate rather than in the direction perpendicular to the upper surface of the substrate, and may thus be deposited even in areas hidden by the tips TIP of the second bank material layer BNL2.

The deposition process of forming the common electrodes CE1, CE2, and CE3 (operation S70) may be performed in an inclined direction relatively closer to a horizontal direction than the deposition process of forming the light-emitting layers EL1, EL2, and EL3 (operation S60). Accordingly, the common electrodes CE1, CE2, and CE3 may contact side surfaces of the first bank material layer BNL1 in greater areas than the light-emitting layers EL1, EL2, and EL3. In an alternative embodiment, the common electrodes CE1, CE2, and CE3 may be deposited up to a higher position on the side surfaces of the first bank material layer BNL1 than the light-emitting layers EL1, EL2, and EL3. Different common electrodes CE1, CE2, and CE3 may contact the first bank material layer BNL1 having relatively high conductivity to be electrically connected to each other. In an embodiment, an organic pattern material layer forming the organic patterns ELP1, ELP2, and ELP3 may be formed with the light-emitting layers EL1, EL2, and EL3, and an electrode pattern material layer forming form the electrode patterns CEP1, CEP2, and CEP3 may be formed with common electrodes CE1, CE2, and CE3, but the disclosure is not limited thereto.

Subsequently, a first inorganic material layer TL1 covering the first light-emitting element ED1 and the capping layer CAP is formed (operation S80). The first inorganic material layer TL1 may be formed to completely cover outer surfaces of the first light-emitting element ED1, the bank material layers BNL1 and BNL2, the capping layer CAP, and the trace pattern. Specifically, the first inorganic material layer TL1 is formed on an upper surface of the first common electrode CE1, side surfaces of the first bank material layer BNL1, a lower surface and side surfaces of the second bank material layer BNL2, and an upper surface and side surfaces of the trace pattern.

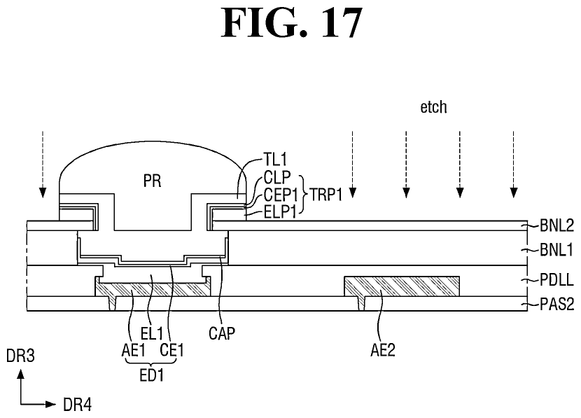

Next, referring to FIG. 17, a photoresist PR of a mask pattern is formed on the first inorganic layer TL1, and a third etching process (3^{rd} etching) of removing the first inorganic layer TL1 and the trace pattern (e.g., the organic pattern material layer and the electrode pattern material layer) that are not covered with the mask pattern is performed (operation S90). In this case, the photoresist PR may be disposed to overlap the first emission area EA1 and an edge area surrounding the first emission area EA1.

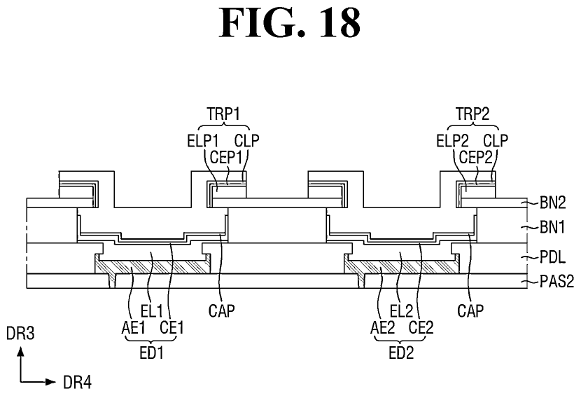

Subsequently, the processes as illustrated in FIGS. 12 to 17 are similarly performed to form the second light-emitting layer EL2, the second common electrode CE2, and the capping layer CAP on the second pixel electrode AE2 as illustrated in FIG. 18, the second trace pattern TRP2 surrounding the second light-emitting layer EL2, the second common electrode CE2, and the capping layer CAP is formed, and the second inorganic layer TL2 covering the second light-emitting element ED2 and the second trace pattern TRP2 is formed.

Subsequently, although not illustrated in the drawings, the display device 10 is fabricated by forming the organic encapsulation film TFE2 and the second inorganic encapsulation film TFE3 of the thin film encapsulation layer TFEL, the light-blocking layer BM, the color filter layer CFL, and the overcoat layer OC (refer to FIG. 6) on the light-emitting elements ED1, ED2, and ED3 and the bank structure BNS. Structures of the thin film encapsulation layer TFEL, the light-blocking layer BM, the color filter layer CFL, and the overcoat layer OC are the same as those described above, and a detailed description thereof will thus be omitted.

The embodiments of the disclosure have been described hereinabove with reference to the accompanying drawings, but it will be understood by one of ordinary skill in the art to which the disclosure pertains that various modifications and alterations may be made without departing from the technical spirit or essential feature of the disclosure. Therefore, it is to be understood that the embodiments described above are illustrative rather than being restrictive in all features.

What is claimed is:

1. A display device comprising:
a first pixel electrode disposed on a substrate and including:
a main portion; and
an edge portion surrounding the main portion;
a pixel defining film disposed on the substrate, including:
a body portion; and
a protrusion portion protruding from the body portion and exposing the first pixel electrode;
a first light-emitting layer disposed on the first pixel electrode;
a first common electrode disposed on the first light-emitting layer;
a first bank layer disposed on the pixel defining film; and
a second bank layer disposed on the first bank layer and including a side surface protruding further than a side surface of the first bank layer,
wherein a thickness of the edge portion of the first pixel electrode is greater than a thickness of the main portion of the first pixel electrode, and
a width of the protrusion portion of the pixel defining film is greater than a width of the edge portion of the first pixel electrode.

2. The display device of claim 1, wherein a difference between the thickness of the edge portion of the first pixel electrode and the thickness of the main portion of the first pixel electrode is about 150 angstroms to about 300 angstroms.

3. The display device of claim 1, wherein the first pixel electrode includes a lower transparent electrode layer disposed on the substrate, a metal electrode layer disposed on the lower transparent electrode layer, and an upper transparent electrode layer disposed on the metal electrode layer, and
a thickness of the edge portion of the upper transparent electrode layer is greater than a thickness of the main portion of the upper transparent electrode layer.

4. The display device of claim 3, wherein the thickness of the edge portion of the upper transparent electrode layer is about 400 angstroms to about 700 angstroms, and
the thickness of the main portion of the upper transparent electrode layer is about 100 angstroms to about 500 angstroms.

5. The display device of claim 3, wherein a thickness of the lower transparent electrode layer is about 30 angstroms to about 100 angstroms, and
a thickness of the metal electrode layer is about 700 angstroms to about 1000 angstroms.

6. The display device of claim 3, wherein the lower transparent electrode layer and the upper transparent electrode layer include indium tin oxide, and
the metal electrode layer includes silver (Ag).

7. The display device of claim 1, wherein a lower surface of the protrusion portion of the pixel defining film contacts the edge portion of the first pixel electrode and the first light-emitting layer.

8. The display device of claim 1, wherein a width at which a side surface of the protrusion portion of the pixel defining film protrudes further than the side surface of the first bank layer is greater than a width at which the side surface of the second bank layer protrudes further than the side surface of the first bank layer.

9. The display device of claim 1, wherein the first bank layer includes aluminum (Al), and
the second bank layer includes titanium (Ti).

10. The display device of claim 1, wherein the first common electrode contacts the first bank layer.

11. The display device of claim 1, wherein a maximum distance from the substrate to the first common electrode is smaller than a maximum distance from the substrate to the first bank layer.

12. The display device of claim 1, further comprising a first inorganic layer disposed on an upper surface of the first common electrode, the side surface of the first bank layer, and a lower surface and an upper surface of the second bank layer.

13. The display device of claim 12, further comprising:
a second pixel electrode spaced apart from the first pixel electrode on the substrate and including:
a main portion; and
an edge portion surrounding the main portion;
a second light-emitting layer disposed on the second pixel electrode;
a second common electrode disposed on the second light-emitting layer and spaced apart from the first common electrode; and
a second inorganic layer disposed on an upper surface of the second common electrode, the side surface of the first bank layer, and the lower surface and the upper surface of the second bank layer,
wherein the pixel defining film exposes the second pixel electrode,
the first inorganic layer and the second inorganic layer are spaced apart from each other, and
a portion of the second bank layer is exposed in a space between the first inorganic layer and the second inorganic layer spaced apart from each other.

14. The display device of claim 1, further comprising:
a first organic pattern disposed on the second bank layer and including a same material as a material of the first light-emitting layer; and
a first electrode pattern disposed on the first organic pattern and including a same material as a material of the first common electrode,
wherein the first light-emitting layer and the first organic pattern are separated from each other, and
the first common electrode and the first electrode pattern are separated from each other.

15. A method for fabrication of a display device, the method comprising:
forming a plurality of pixel electrodes spaced apart from each other on a substrate;
forming a pixel defining material layer on the plurality of pixel electrodes, forming a first bank material layer on the pixel defining material layer, and forming a second bank material layer on the first bank material layer;
defining a hole exposing a first pixel electrode of the plurality of pixel electrodes by etching the pixel defining material layer, the first bank material layer, and the second bank material layer;
etching a portion of the first pixel electrode so that portions of a lower surface of the pixel defining material layer are exposed while etching side surfaces of the first bank material layer exposed through the hole so that portions of a lower surface of the second bank material layer are exposed;
forming a first light-emitting layer on the first pixel electrode and forming a first common electrode on the first light-emitting layer; and
forming a first inorganic material layer on the first common electrode.

16. The method for fabrication of a display device of claim 15, wherein the forming the plurality of pixel electrodes spaced apart from each other on the substrate includes forming an amorphous indium tin oxide electrode including hydrogen through a sputtering process under at an atmosphere of a mixed gas including hydrogen and argon.

17. The method for fabrication of a display device of claim 16, further comprising, between the etching the portion of the first pixel electrode while etching the side surfaces of the first bank material layer and the forming the first light-emitting layer on the first pixel electrode, crystallizing the indium tin oxide electrode by heat-treating the first pixel electrode to remove hydrogen in the indium tin oxide electrode.

18. The method for fabrication of a display device of claim 15, wherein in the etching the portion of the first pixel electrode so that the portions of the lower surface of the pixel defining material layer are exposed while etching the side surfaces of the first bank material layer exposed through the hole so that the portions of the lower surface of the second bank material layer are exposed,
the first pixel electrode including a main portion and an edge portion surrounding the main portion is formed, and
a thickness of the edge portion of the first pixel electrode is greater than a thickness of the main portion of the first pixel electrode.

19. The method for fabrication of a display device of claim 15, wherein in the forming the first light-emitting layer on the first pixel electrode and the forming the first common electrode on the first light-emitting layer, a first organic pattern material layer separated from the first light-emitting layer is formed on the second bank material layer, and a first electrode pattern material layer separated from the first common electrode is formed on the first organic pattern material layer, and
in the forming the first inorganic material layer on the first common electrode, the first inorganic material layer connected without being disconnected is formed on the first common electrode and the first electrode pattern material layer.

20. The method for fabrication of a display device of claim 19, further comprising forming a mask pattern on the first inorganic material layer overlapping the first pixel electrode and etching the first organic pattern material layer, the first electrode pattern material layer, and the first inorganic material layer which are not covered by the mask pattern through an etching process.
